(19) United States
(12) Patent Application Publication
(10) Pub. No.: US 2025/0089252 A1
(43) Pub. Date: Mar. 13, 2025

(54) SEMICONDUCTOR DEVICES

(71) Applicant: Samsung Electronics Co., Ltd., Suwon-si (KR)

(72) Inventors: Jongseon AHN, Suwon-si (KR); Hyunju KIM, Suwon-si (KR); Jaehwang SIM, Suwon-si (KR); Seulbi LEE, Suwon-si (KR)

(73) Assignee: Samsung Electronics Co., Ltd., Suwon-si (KR)

(21) Appl. No.: 18/820,966

(22) Filed: Aug. 30, 2024

(30) Foreign Application Priority Data
Sep. 12, 2023 (KR) 10-2023-0121268

(51) Int. Cl. H10B 43/27

(52) U.S. Cl. CPC H10B 43/27

(57) ABSTRACT

A semiconductor device includes a gate electrode structure, a memory channel structure, and a contact plug. The gate electrode structure includes gate electrodes sequentially stacked and spaced apart from each other on a substrate in a first direction perpendicular to an upper surface of the substrate. Each of the gate electrodes extends in a second direction substantially parallel to the upper surface of the substrate. The memory channel structure extends through the gate electrode structure. The contact plug extends partially through the gate electrode structure to contact an upper surface of a first gate electrode among the gate electrodes. The contact plug is electrically insulated from a second gate electrode that is over the first gate electrode. At least a portion of the contact plug has a width decreasing from a top toward a bottom thereof in the first direction in a stepwise manner.

### CROSS-REFERENCE TO RELATED APPLICATION

This application claims priority under 35 U.S.C. § 119 to Korean Patent Application No. 10-2023-0121268 filed on Sep. 12, 2023 in the Korean Intellectual Property Office, the disclosure of which is hereby incorporated by reference in its entirety.

### BACKGROUND

### Technical Field

The inventive concepts relate to semiconductor devices. More particularly, the inventive concepts relate to vertical memory devices.

### Discussion of Related Art

In an electronic system requiring data storage, a high capacity semiconductor device that may store high capacity data is desirable. Thus, a method of increasing the data storage capacity of the semiconductor device has been studied. For example, a semiconductor device including memory cells that may be 3-dimensionally stacked has been suggested.

Research on a method of efficiently forming contact plugs for transferring electrical signals to memory cells in the semiconductor device is required.

### SUMMARY

Some example embodiments provide semiconductor devices having improved electrical characteristics.

According to an example embodiment, a semiconductor device may include a gate electrode structure, a memory channel structure, and a contact plug. The gate electrode structure may be on a substrate, and may include gate electrodes sequentially stacked and spaced apart from each other in a first direction, the first direction being substantially perpendicular to an upper surface of the substrate. Each of the gate electrodes may extend in a second direction, the second direction being substantially parallel to the upper surface of the substrate. The memory channel structure may extend through the gate electrode structure. The contact plug may extend partially through the gate electrode structure to contact an upper surface of a first gate electrode among the gate electrodes. The contact plug may extend through but be electrically insulated from a second gate electrode that is over the first gate electrode. At least a portion of the contact plug may have a width decreasing from a top toward a bottom thereof in the first direction in a stepwise manner.

According to an example embodiment, a semiconductor device may include a gate electrode structure, a memory channel structure, an insulating interlayer and a contact plug. The gate electrode structure may be on a substrate, and may include gate electrodes sequentially stacked and spaced apart from each other in a first direction, the first direction being substantially perpendicular to an upper surface of the substrate. Each of the gate electrodes may extend in a second direction, the second direction being substantially parallel to the upper surface of the substrate. The memory channel structure may extend through the gate electrode structure. The insulating interlayer may be disposed on the gate electrode structure and the memory channel structure. The contact plug may extend through the insulating interlayer and a portion of the gate electrode structure to contact an upper surface of a first one of the gate electrodes. The contact plug may extend through but be electrically insulated from a second one of the gate electrodes that is over the first one of the gate electrodes. The contact plug may include first and second lower portions stacked in the first direction and extending through the portion of the gate electrode structure, and an upper portion on the second lower portion and extending through the insulating interlayer. Each of the first and second lower portions may have a width decreasing from a top toward a bottom thereon in the first direction in a stepwise manner.

According to an example embodiment, a semiconductor device may include a gate electrode structure, memory channel structures, support structures, an insulating interlayer and first contact plugs. The gate electrode structure may include first gate electrodes and a second gate electrode. The first gate electrodes may be on first and second regions of a substrate, and may be sequentially stacked and spaced apart from each other in a first direction, the first direction being substantially perpendicular to an upper surface of the substrate. Each of the gate electrodes may extend in a second direction, the second direction being substantially parallel to the upper surface of the substrate. The second gate electrode may be over the first gate electrodes on the first region and a portion of the second region adjacent to the first region of the substrate. The memory channel structures may extend through the gate electrode structure on the first region of the substrate. The support structures may extend through the first gate electrodes on the second region of the substrate. The insulating interlayer may be on the substrate, and may cover the gate electrode structure, the memory channel structures and the support structures. Each of the first contact plugs may extend through the insulating interlayer and at least one of the first gate electrodes to contact a first one of the first gate electrodes. Each of the first contact plugs may extend through but be electrically insulated from a second one of the first gate electrodes that is over the first one of the first gate electrodes. Each of the first contact plugs may include an upper portion extending through the insulating interlayer and a lower portion under the upper portion. At least a portion of the lower portion may have a width decreasing from a top toward a bottom thereof in the first direction.

In the method of manufacturing the semiconductor device in accordance with an example embodiment, the process for forming the contact plugs that may contact a corresponding one of the gate electrodes to be electrically connected thereto may be simplified.

### BRIEF DESCRIPTION OF THE DRAWINGS

FIGS. 1 to 8 are plan views and cross-sectional views illustrating a method of forming a hole in accordance with some example embodiments.

FIGS. 9 to 12 are plan views and cross-sectional views illustrating a semiconductor device in accordance with an example embodiment.

FIGS. 13 to 46 are plan views and cross-sectional views illustrating a method of manufacturing a semiconductor device according to an example embodiment.

FIG. 47 is a cross-sectional view illustrating a semiconductor device in accordance with an example embodiment.

FIGS. 48 to 55 are cross-sectional views illustrating a method of manufacturing a semiconductor device of FIG. 47.

### DETAILED DESCRIPTION

The above and other aspects and features of the semiconductor devices and the methods of manufacturing the same in accordance with example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Hereinafter, a vertical direction substantially perpendicular to an upper surface of a substrate may be referred to as a first direction D1, and two directions crossing each other among horizontal directions substantially parallel to the upper surface of the substrate may be referred to as second and third directions D2 and D3, respectively. In some example embodiments, the second and third directions D2 and D3 may be substantially perpendicular to each other. Each of the first to third directions D1, D2 and D3 may include both a direction indicated by an arrow and a direction inverse thereto, in the drawings.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

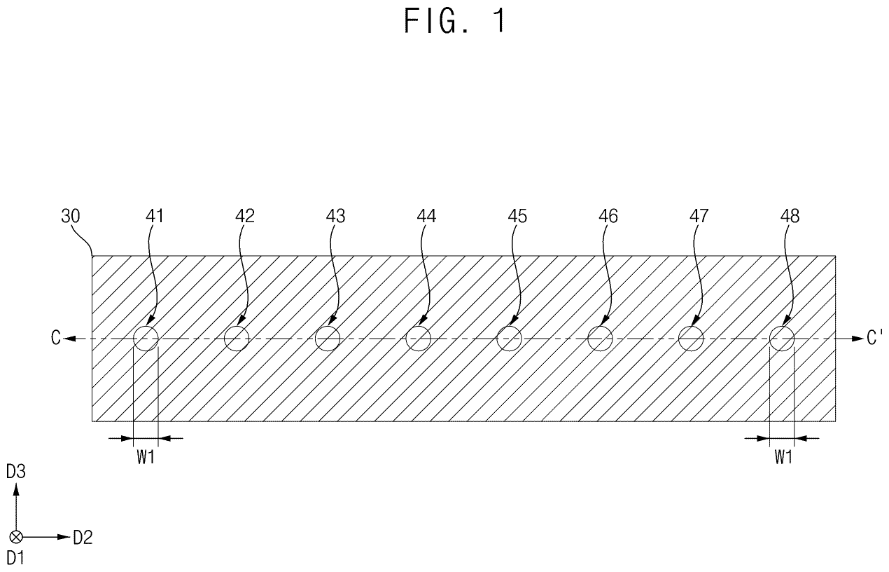

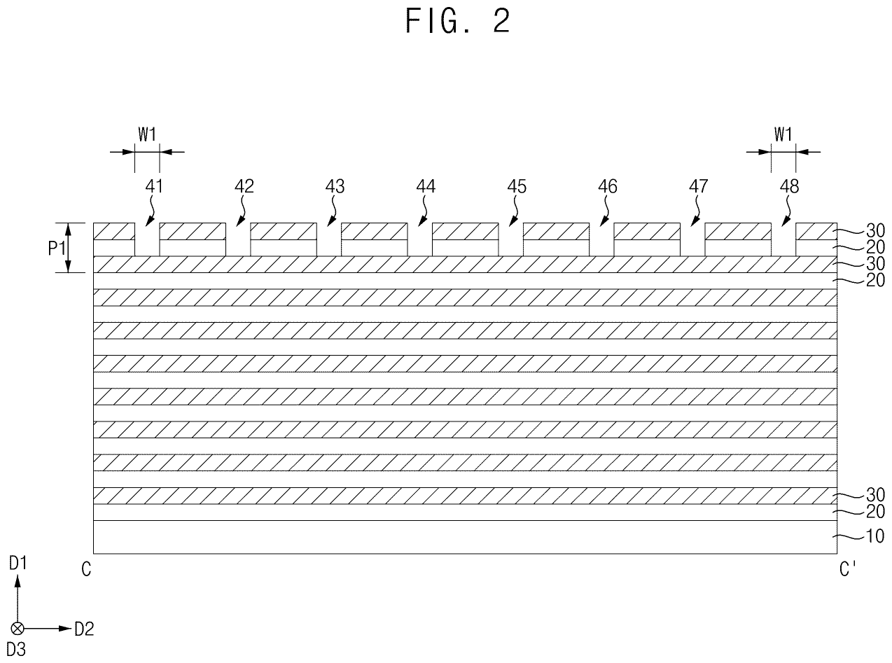

FIGS. 1 to 8 are plan views and cross-sectional views illustrating a method of forming a hole in accordance with some example embodiments. For example, FIGS. 1, 3, 5 and 7 are the plan views, and FIGS. 2, 4, 6 and 8 are cross-sectional views taken along lines C-C′ of corresponding plan views, respectively.

Referring to FIGS. 1 and 2, an insulation layer 20 and a sacrificial layer 30 may be alternately and repeatedly stacked on a substrate 10 to form a mold layer.

The substrate 10 may include a semiconductor material (e.g., silicon, germanium, silicon-germanium, etc.), or a III-V group compound semiconductor (e.g., GaP, GaAs, GaSb, etc.). In some example embodiments, the substrate 10 may be a silicon-on-insulator (SOI) substrate or a germanium-on-insulator (GOI) substrate.

In some example embodiments, the insulation layer 20 may include oxide (e.g., silicon oxide), and the sacrificial layer 30 may include a material having an etching selectivity with respect to the insulation layer 20 (e.g., an insulating nitride such as silicon nitride).

A first photoresist pattern may be formed on an uppermost one of the sacrificial layers 30, which may be disposed at an uppermost level among the sacrificial layers 30, and a first etching process may be performed using the first photoresist pattern as an etching mask to partially remove two upper layers of the mold layer, that is, the uppermost one of the sacrificial layers 30 and an uppermost one of the insulation layers 20, which may be disposed at an uppermost level among the insulation layers 20, and thus first to eighth holes 41, 42, 43, 44, 45, 46, 47 and 48 may be formed to expose an upper surface of the sacrificial layer 30 that is disposed at a second level from above among the sacrificial layers 30.

In some example embodiments, each of the first to eighth holes 41, 42, 43, 44, 45, 46, 47 and 48 may have a first width W1 in the horizontal direction and a first depth P1 in the first direction D1 from an upper surface of the uppermost one of the sacrificial layers 30.

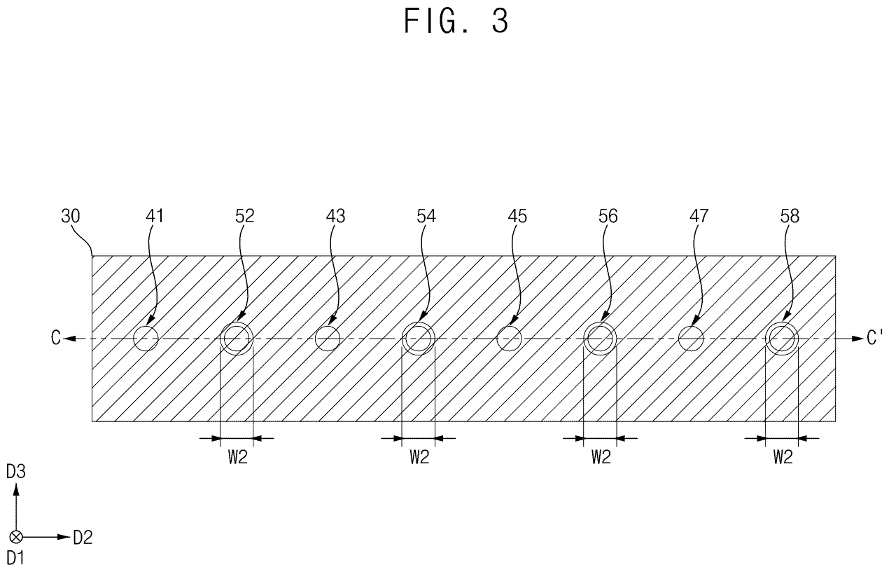

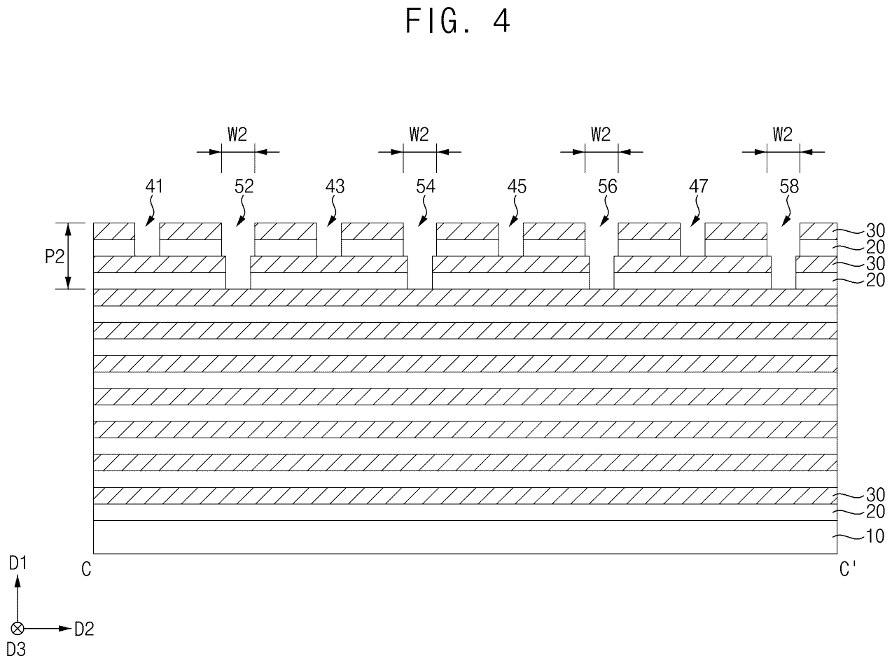

Referring to FIGS. 3 and 4, the uppermost one of the sacrificial layers 30, one of the sacrificial layers 30 that is disposed at a second level from above among the sacrificial layers 30, the uppermost one of the insulation layers 20, and one of the insulation layers 20 that is disposed at a second level from above among the insulation layers 20 may be partially removed to form ninth to twelfth holes 52, 54, 56 and 58 spaced apart from each other in the second direction D2 and exposing an upper surface of one of the sacrificial layers 30 that is disposed at a third level from above among the sacrificial layers 30.

In some example embodiments, the ninth to twelfth holes 52, 54, 56 and 58 may be formed by performing a second etching process using a second photoresist pattern as an etching mask that may expose portions of the upper surface of the uppermost one of the sacrificial layers 30 adjacent to even-numbered ones of the first to eighth holes 41, 42, 43, 44, 45, 46, 47 and 48, that is, the second, fourth, sixth and eighth holes 42, 44, 46 and 48, respectively, on the two upper layers of the mold layer, that is, the uppermost one of the sacrificial layers 30 and the uppermost one of the insulation layers 20, and two upper layers under the second, fourth, sixth and eighth holes 42, 44, 46 and 48, that is, the one of the sacrificial layers 30 that is disposed at the second level from above among the sacrificial layers 30 and the one of the insulation layers 20 that is disposed at the second level from above among the insulation layers 20.

Thus, each of the ninth to twelfth holes 52, 54, 56 and 58 may include a lower portion having a first width W1 and extending through the one of the sacrificial layers 30 that is disposed at the second level from above among the sacrificial layers 30 and the one of the insulation layers 20 that is disposed at the second level from above among the insulation layers 20, and an upper portion having a second width W2 greater than the first width W1 and extending through the uppermost one of the sacrificial layers 30 and the uppermost one of the insulation layers 20. Each of the ninth to twelfth holes 52, 54, 56 and 58 may have a second depth P2 in the first direction D1 from the upper surface of the uppermost one of the sacrificial layers 30, which may be greater than the first depth P1.

As the ninth to twelfth holes 52, 54, 56 and 58 are formed, the first, ninth, third, tenth, fifth, eleventh, seventh and twelfth holes 41, 52, 43, 54, 45, 56, 47 and 58 may be formed to be spaced apart from each other in the second direction D2 in this order.

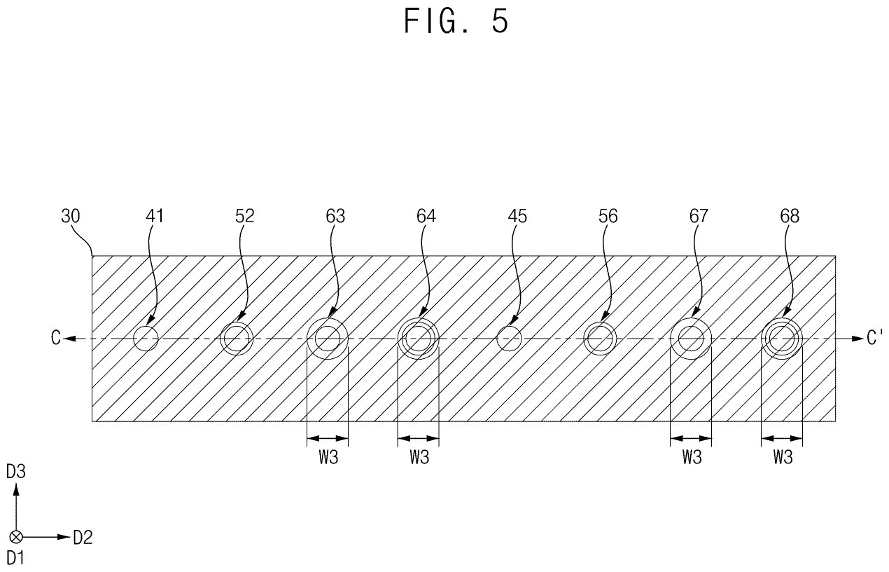

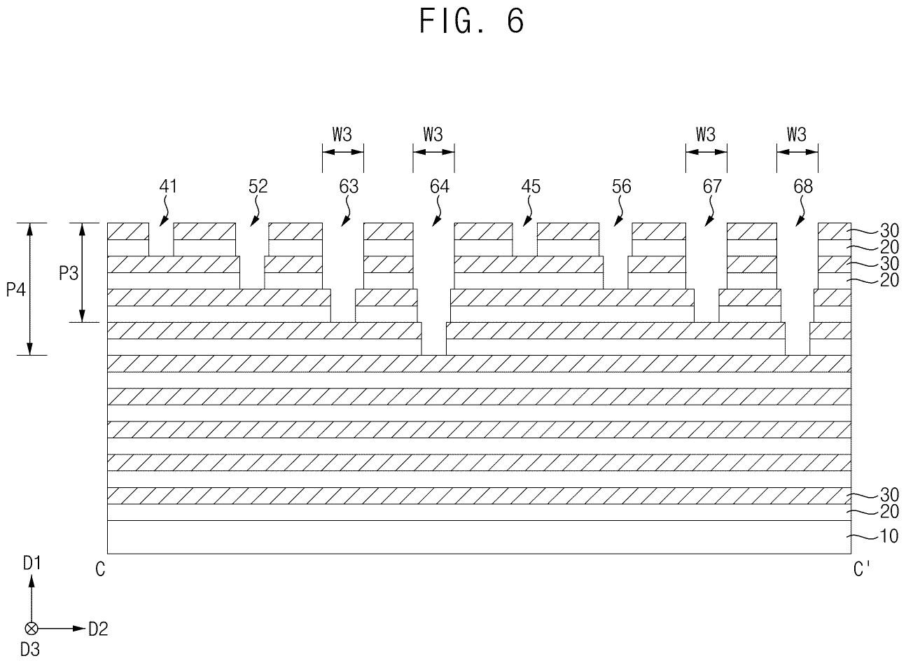

Referring to FIGS. 5 and 6, the uppermost one of the sacrificial layers 30, ones of the sacrificial layers 30 that are disposed at the second level, the third level and a fourth level, respectively, from above among the sacrificial layers 30, the uppermost one of the insulation layers 20, and ones of the insulation layers 20 that are disposed at the second level, a third level and a fourth level, respectively, from above among the insulation layers 20 may be partially removed to form thirteenth to sixteenth holes 63, 64, 67 and 68 spaced apart from each other in the second direction D2 and exposing an upper surface of the one of the sacrificial layers 30 that is disposed at the fourth level from above or an upper surface of one of the sacrificial layers 30 that is disposed at a fifth level from above among the sacrificial layers 30.

In some example embodiments, the thirteenth to sixteenth holes 63, 64, 67 and 68 may be formed by a third etching process using a third photoresist pattern as an etching mask that may expose portions of the upper surface of the uppermost one of the sacrificial layers 30 that are adjacent to the third, fourth, seventh and eighth holes among the first, ninth, third, tenth, fifth, eleventh, seventh and twelfth holes 41, 52, 43, 54, 45, 56, 47 and 58 spaced apart from each other in the second direction D2, that is, the third, tenth, seventh and twelfth holes 43, 54, 47 and 58, respectively, on the two upper layers of the mold layer, that is, the uppermost one of the sacrificial layers 30 and the uppermost one of the insulation layers 20, and two upper layers under the third, tenth, seventh and twelfth holes 43, 54, 47 and 58, that is, the ones of the sacrificial layers 30 that are disposed at the third and fourth levels, respectively, from above among the sacrificial layers 30 and the ones of the insulation layers 20 that are disposed at the third and fourth levels, respectively, from above among the insulation layers 20.

Thus, each of the thirteenth and fifteenth holes 63 and 67 may include a lower portion having the first width W1 and extending through the one of the sacrificial layers 30 that is disposed at the third level from above among the sacrificial layers 30 and the one of the insulation layers 20 that is disposed at the third level from above among the insulation layers 20, and an upper portion having a third width W3 greater than the second width W2 and extending through the uppermost one of the sacrificial layers 30, the one of the sacrificial layers 30 that is disposed at the second level from above, the uppermost one of the insulation layers 20 and the one of the insulation layers 30 that is disposed at the second level from above. Each of the thirteenth and fifteenth holes 63 and 67 may have a third depth P3 in the first direction D1 from the upper surface of the uppermost one of the sacrificial layers 30, which may be greater than the second depth P2.

Additionally, each of the fourteenth and sixteenth holes 64 and 68 may include a lower portion having the first width W1 and extending through the one of the sacrificial layers 30 that is disposed at the fourth level from above among the sacrificial layers 30 and the one of the insulation layers 20 that is disposed at the fourth level from above among the insulation layers 20, a middle portion having the second width W2 and extending through the one of the sacrificial layers 30 that is disposed at the third level from above among the sacrificial layers 30 and the one of the insulation layers 20 that is disposed at the third level from above among the insulation layers 20, and an upper portion having the third width W3 greater than the second width W2 and extending through the uppermost one of the sacrificial layers 30, the one of the sacrificial layers 30 that is disposed at the second level from above, the uppermost one of the insulation layers 20, and the one of the insulation layers 30 that is disposed at the second level from above. Each of the fourteenth and sixteenth holes 64 and 68 may have a fourth depth P4 in the first direction D1 from the upper surface of the uppermost one of the sacrificial layers 30, which may be greater than the third depth P3.

As the thirteenth to sixteenth holes 63, 64, 67 and 68 are formed, the first, ninth, thirteenth, fourteenth, fifth, eleventh, fifteenth and sixteenth holes 41, 52, 63, 64, 45, 56, 67 and 68 may be formed to be spaced apart from each other in the second direction D2 in this order.

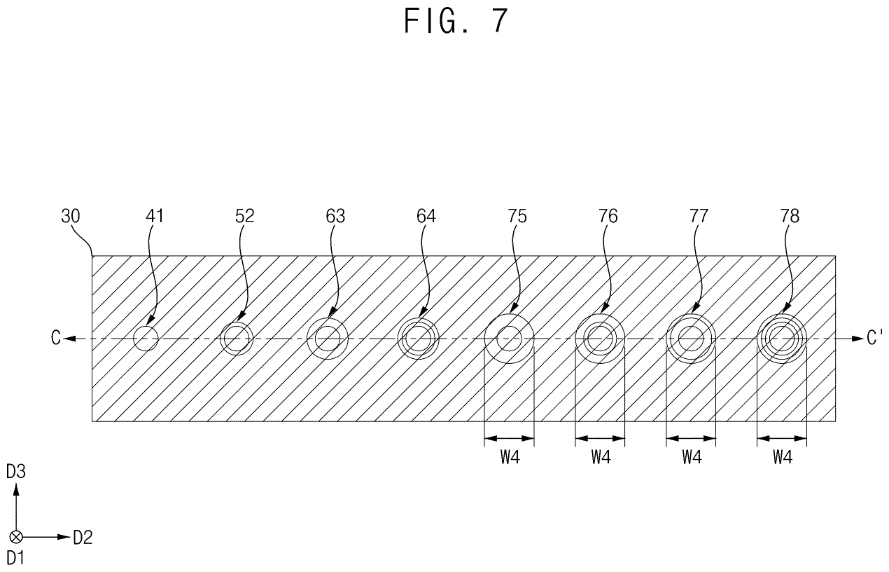

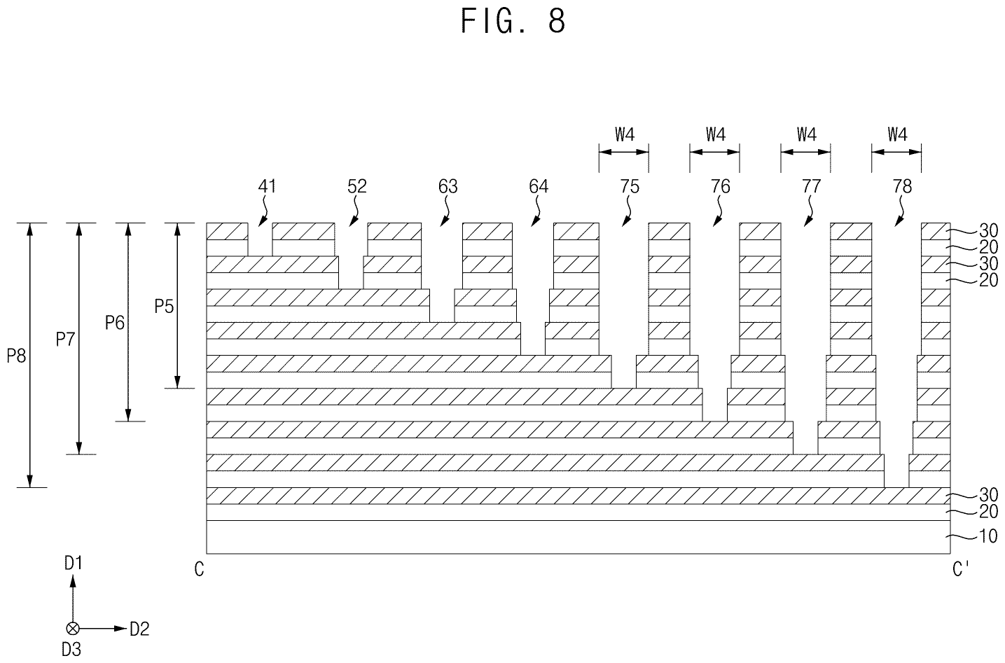

Referring to FIGS. 7 and 8, the uppermost one of the sacrificial layers 30, the ones of the sacrificial layers 30 that are disposed at the second to fifth levels, respectively, one of the sacrificial layers 30 that are disposed at sixth to eighth levels, respectively, from above among the sacrificial layers 30, the uppermost one of the insulation layers 20, the ones of the insulation layers 20 that are disposed at the second to fourth levels, respectively, and one of the insulation layers 20 that are disposed at fifth to eighth levels, respectively, from above among the insulation layers 20 may be partially removed to form seventeenth to twentieth holes 75, 76, 77 and 78 spaced apart from each other in the second direction D2 and exposing an upper surface of the one of the sacrificial layers 30 that is disposed at one of the sixth to ninth levels.

In some example embodiments, the seventeenth to twentieth holes 75, 76, 77 and 78 may be formed by a fourth etching process using a fourth photoresist pattern as an etching mask that may expose portions of the upper surface of the uppermost one of the sacrificial layers 30 that are adjacent to the fifth, eleventh, fifteenth and sixteenth holes 45, 56, 67 and 68, respectively (e.g., the fifth, sixth, seventh and eighth holes among the first, ninth, thirteenth, fourteenth, fifth, eleventh, fifteenth and sixteenth holes 41, 52, 63, 64, 45, 56, 67 and 68 spaced apart from each other in the second direction D2), on the two upper layers of the mold layer (e.g., the uppermost one of the sacrificial layers 30 and the uppermost one of the insulation layers 20), and two upper layers under the fifth, eleventh, fifteenth and sixteenth holes 45, 56, 67 and 68 (e.g., the ones of the sacrificial layers 30 that are disposed at the second to fifth levels, respectively, from above among the sacrificial layers 30 and the ones of the insulation layers 20 that are disposed at the second to fifth levels, respectively, from above among the insulation layers 20).

Thus, the seventeenth hole 75 may include a lower portion having the first width W1 and extending through the one of the sacrificial layers 30 that is disposed at the fifth level from above among the sacrificial layers 30 and the one of the insulation layers 20 that is disposed at the fifth level from above among the insulation layers 20, and an upper portion having a fourth width W4 greater than the third width W3 and extending through the uppermost one of the sacrificial layers 30, the ones of the sacrificial layers 30 that are disposed at the second to fourth levels, respectively, from above, the uppermost one of the insulation layers 20, and the ones of the insulation layers 30 that are disposed at the second to fourth levels, respectively, from above. The seventeenth hole 75 may have a fifth depth P5 in the first direction D1 from the upper surface of the uppermost one of the sacrificial layers 30, which may be greater than the fourth depth P4.

Additionally, the eighteenth hole 76 may include a lower portion having the first width W1 and extending through the one of the sacrificial layers 30 that is disposed at the sixth level from above among the sacrificial layers 30 and the one of the insulation layers 20 that is disposed at the fifth level from above among the insulation layers 20, a middle portion having the second width W2 and extending through the one of the sacrificial layers 30 that is disposed at the fifth level from above among the sacrificial layers 30 and the one of the insulation layers 20 that is disposed at the fifth level from above among the insulation layers 20, and an upper portion having the fourth width W4 and extending through the uppermost one of the sacrificial layers 30, the ones of the sacrificial layers 30 that are disposed at the second to fourth levels, respectively, from above, the uppermost one of the insulation layers 20, and the ones of the insulation layers 30 that are disposed at the second to fourth levels, respectively, from above. The eighteenth hole 76 may have a sixth depth P6 in the first direction D1 from the upper surface of the uppermost one of the sacrificial layers 30, which may be greater than the fifth depth P5.

Additionally, the nineteenth hole 77 may include a lower portion having the first width W1 and extending through the one of the sacrificial layers 30 that is disposed at the seventh level from above among the sacrificial layers 30 and the one of the insulation layers 20 that is disposed at the seventh level from above among the insulation layers 20, a middle portion having the third width W3 and extending through the ones of the sacrificial layers 30 that are disposed at the fifth and sixth levels, respectively, from above among the sacrificial layers 30 and the ones of the insulation layers 20 that are disposed at the fifth and sixth levels, respectively, from above among the insulation layers 20, and an upper portion having the fourth width W4 and extending through the uppermost one of the sacrificial layers 30, the ones of the sacrificial layers 30 that are disposed at the second to fourth levels, respectively, from above, the uppermost one of the insulation layers 20 and the ones of the insulation layers 30 that are disposed at the second to fourth levels, respectively, from above. The nineteenth hole 77 may have a seventh depth P7 in the first direction D1 from the upper surface of the uppermost one of the sacrificial layers 30, which may be greater than the sixth depth P6.

Additionally, the twentieth hole 78 may include a lower portion having the first width W1 and extending through the one of the sacrificial layers 30 that is disposed at the eighth level from above among the sacrificial layers 30 and the one of the insulation layers 20 that is disposed at the eighth level from above among the insulation layers 20, a first middle portion having the second width W2 and extending through the one of the sacrificial layers 30 that is disposed at the seventh level from above among the sacrificial layers 30 and the one of the insulation layers 20 that is disposed at the seventh level from above among the insulation layers 20, a second middle portion having the third width W3 and extending through the ones of the sacrificial layers 30 that are disposed at the fifth and sixth levels, respectively, from above among the sacrificial layers 30 and the ones of the insulation layers 20 that are disposed at the fifth and sixth levels, respectively, from above among the insulation layers 20, and an upper portion having the fourth width W4 and extending through the uppermost one of the sacrificial layers 30, the ones of the sacrificial layers 30 that are disposed at the second to fourth levels, respectively, from above, the uppermost one of the insulation layers 20 and the ones of the insulation layers 30 that are disposed at the second to fourth levels, respectively, from above. The twentieth hole 78 may have an eighth depth P8 in the first direction D1 from the upper surface of the uppermost one of the sacrificial layers 30, which may be greater than the seventh depth P7.

As the seventeenth to twentieth holes 75, 76, 77 and 78 are formed, the first, ninth, thirteenth, fourteenth, seventeenth, eighteenth, nineteenth and twentieth holes 41, 52, 63, 64, 75, 76, 77 and 78 may be formed to be spaced apart from each other in the second direction D2 in this order.

By the above processes, the first, ninth, thirteenth, fourteenth, seventeenth, eighteenth, nineteenth and twentieth holes 41, 52, 63, 64, 75, 76, 77 and 78, each of which may partially extend through the mold layer, may be formed to be spaced apart from each other in the second direction D2. The first, ninth, thirteenth, fourteenth, seventeenth, eighteenth, nineteenth and twentieth holes 41, 52, 63, 64, 75, 76, 77 and 78 may expose different ones of the sacrificial layer 30 that are disposed at different levels, respectively, and may have different depths P1, P2, P3, P4, P5, P6 P7 and P8, respectively.

Thus, when the sacrificial layers 30 are replaced with gate electrodes including a conductive material, an insulation spacer is formed on sidewalls of the first, ninth, thirteenth, fourteenth, seventeenth, eighteenth, nineteenth and twentieth holes 41, 52, 63, 64, 75, 76, 77 and 78, and contact plugs are formed therein, each of the contact plugs may contact a corresponding one of the gate electrodes to be electrically connected thereto, and may not be electrically connected to other ones of the gate electrodes that are disposed at other levels.

In some example embodiments, each of the first, ninth, thirteenth, fourteenth, seventeenth, eighteenth, nineteenth and twentieth holes 41, 52, 63, 64, 75, 76, 77 and 78 may have width in the horizontal direction that may decrease from a uppermost level toward an lowermost level in the first direction D1.

In some example embodiments, the first etching process may be performed to form the eight holes (e.g., the first to eighth holes 41, 42, 43, 44, 45, 46, 47 and 48) extending through the uppermost one of the sacrificial layers 30 and the uppermost one of the insulation layers 20, the second etching process for partially removing one of the sacrificial layers 30 at one level and one of the insulation layers 20 at one level may be performed, the third etching process for partially removing ones of the sacrificial layers 30 at two levels, respectively, and ones of the insulation layers 20 at two levels, respectively, may be performed, and the fourth etching process for partially removing ones of the sacrificial layers 30 at four levels, respectively, and ones of the insulation layers 20 at four levels, respectively, may be performed so that the eight holes (e.g., the first, ninth, thirteenth, fourteenth, seventeenth, eighteenth, nineteenth and twentieth holes 41, 52, 63, 64, 75, 76, 77 and 78) spaced apart from each other in the second direction D2 and exposing upper surfaces of the sacrificial layers 30 at different levels, respectively may be formed. However, the inventive concepts may not be limited thereto.

For example, the eight holes (e.g., the first, ninth, thirteenth, fourteenth, seventeenth, eighteenth, nineteenth and twentieth holes 41, 52, 63, 64, 75, 76, 77 and 78) may be defined as a hole group (e.g., one group of holes), eight hole groups (e.g., eight group of holes) spaced apart from each other in the second direction D2 may be formed partially through the mold layer, and processes substantially the same as or similar to the second to fourth etching processes may be performed on the hole groups so that 64 holes exposing upper surfaces of ones of the sacrificial layers 30 at different levels, respectively, may be formed to be spaced apart from each other in the second direction D2.

Thus, 8ⁿ holes (n is a natural number) exposing upper surfaces of 8ⁿ sacrificial layers 30 at different levels, respectively, may be formed to be spaced apart from each other in the second direction D2. In some example embodiments, 2ⁿ holes (n is a natural number) exposing upper surfaces of 2ⁿ sacrificial layers 30 at different levels, respectively, may be formed to be spaced apart from each other in the second direction D2, by changing the number of the holes included in each hole groups or the number of the hole groups.

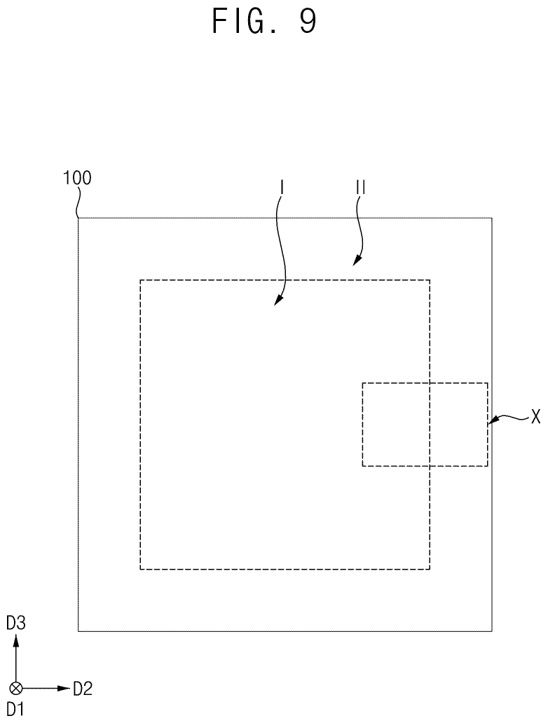

FIGS. 9 to 12 are plan views and cross-sectional views illustrating a semiconductor device in accordance with an example embodiment.

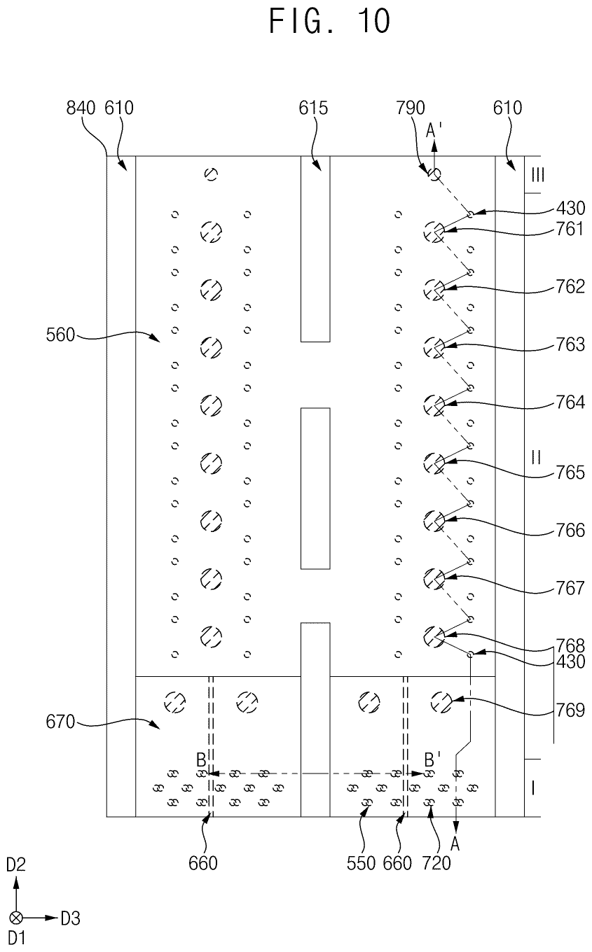

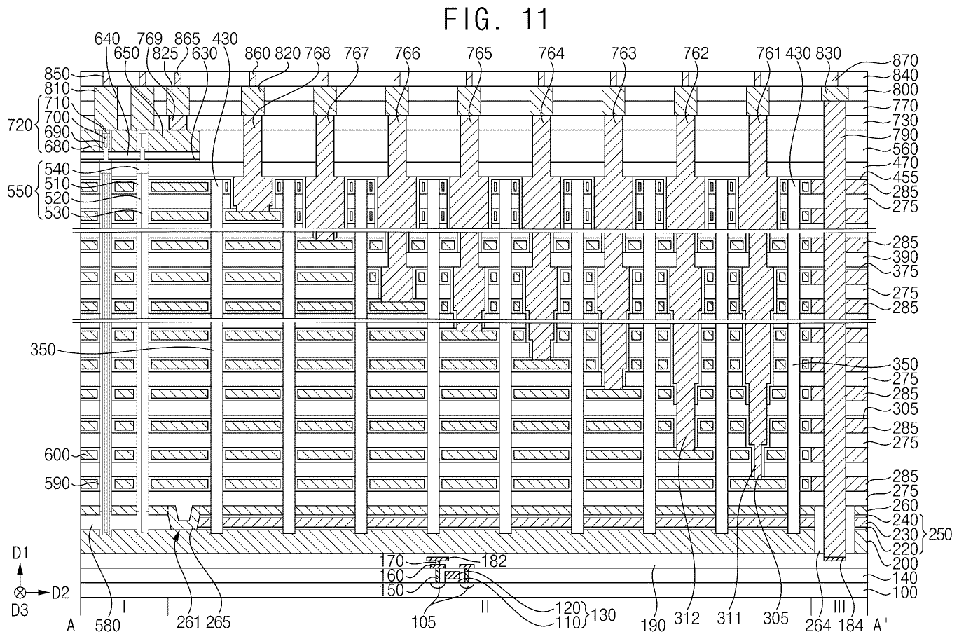

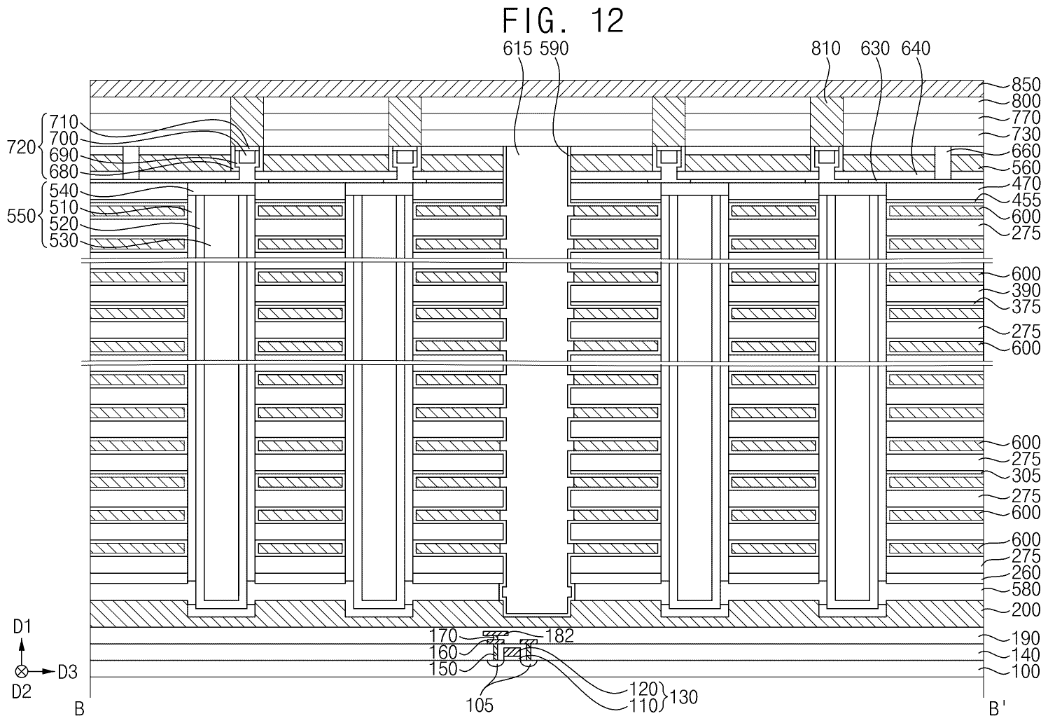

Particularly, FIGS. 9 and 10 are the plan views, FIG. 11 is a cross-sectional view taken along line A-A′ of FIG. 10, and FIG. 12 is a cross-sectional view taken along line B-B′ of FIG. 10. FIGS. 10 to 12 are drawings about region X of FIG. 9.

FIG. 10 does not show upper wirings and upper vias in order to avoid complexity of the drawing.

Referring to FIGS. 9 to 12, the semiconductor device may include a lower circuit pattern, a common source plate (CSP), a gate electrode structure, first to third division patterns 610, 615 and 660, first and second support structures 350 and 430, first and second memory channel structures 550 and 720, first to ninth upper contact plugs 761, 762, 763, 764, 765, 766, 767, 768 and 769, first to third spacers 305, 375 and 455, a through via 790, first to fourth upper vias 810, 820, 825 and 830, and first to fourth upper wirings 850, 860, 865 and 870 on a substrate 100.

In addition, the semiconductor device may include a sacrificial layer structure 250, a support layer 260, a support pattern 265, a channel connection pattern 580, a second blocking pattern 590, first and second insulation patterns 264 and 275, first to tenth insulating interlayers 140, 190, 390, 470, 560, 630, 730, 770, 800 and 840, an etch stop layer 640, and first to third mold layers.

The substrate 100 may include a semiconductor material, for example, silicon, germanium, silicon-germanium, etc., or a III-V group compound semiconductor, for example, GaP, GaAs, GaSb, etc. In some example embodiments, the substrate 100 may be an SOI substrate or a GOI substrate.

The substrate 100 may include first, second and third regions I, II and III. In some example embodiments, the first region I of the substrate 100 may be a cell array region in which memory cells are formed, the second region II of the substrate 100 may be an extension region in which upper contact plugs for transferring electrical signals to the memory cells are formed, and the first and second regions I and II may collectively form a cell region. The third region III of the substrate 100 may be a peripheral circuit region in which peripheral circuit patterns are formed. In some example embodiments, the second region II may surround the first region I, or may be disposed at each of opposite sides in the second direction D2 of the first region T. The third region III may surround the first and second regions I and II.

In some example embodiments, the semiconductor device may have a cell over periphery (COP) structure. That is, the lower circuit pattern may be disposed on the substrate 100, and the memory cells, the upper contact plugs and an upper circuit pattern may be disposed over the lower circuit pattern. The lower circuit pattern may include, for example, lower transistors, lower contact plugs, lower wirings, lower vias, etc. However, the inventive concepts may not be limited thereto, and the semiconductor device may not have the COP structure.

For example, the lower transistor may include a lower gate structure 130 on the substrate 100 and impurity regions 105 at upper portions of the substrate 100 adjacent to the lower gate structure 130, respectively. The impurity regions 105 may serve as a source and a drain, respectively. The lower gate structure 130 may include a lower gate insulation pattern 110 and a lower gate electrode 120 sequentially stacked on the substrate 100.

The first insulating interlayer 140 may be disposed on the substrate 100, and may cover the lower transistor. A first lower contact plug 150 may extend through the first insulating interlayer 140 to contact each of the impurity regions 105. A second lower contact plug may extend through the first insulating interlayer 140 to contact the lower gate electrode 120.

A first lower wiring 160 may be disposed on the first insulating interlayer 140, and may contact an upper surface of the first lower contact plug 150. A lower via 170 and a second lower wiring 182 may be sequentially stacked on the first lower wiring 160. A third lower wiring 184 may be further disposed at the same level as the second lower wiring 182 on the third region III of the substrate 100.

The second insulating interlayer 190 may be disposed on the first insulating interlayer 140, and may cover the first to third lower wirings 160, 182 and 184 and the lower via 170.

The CSP 200 may be disposed on the second insulating interlayer 190. The CSP 200 may include, for example, polysilicon doped with n-type impurities. In some example embodiments, the CSP 200 may include a metal silicide layer and a polysilicon layer doped with n-type impurities sequentially stacked. The metal silicide layer may include, for example, tungsten silicide.

The sacrificial layer structure 250, the channel connection pattern 580, the support layer 260 and the support pattern 265 may be disposed on the CSP 200.

The channel connection pattern 580 may be disposed on the first region I of the substrate 100, and may include an air gap therein. The sacrificial layer structure 250 may be disposed on the second region II of the substrate 100.

The channel connection pattern 580 may include polysilicon doped with n-type impurities or undoped polysilicon. The sacrificial layer structure 250 may include first to third sacrificial layers 220, 230 and 240 sequentially stacked in the first direction D1. Each of the first and third sacrificial layers 220 and 240 may include oxide (e.g., silicon oxide), and the second sacrificial layer 230 may include nitride (e.g., silicon nitride).

The support layer 260 may be disposed on the channel connection pattern 580 and the sacrificial layer structure 250, and may also be disposed in a first opening 261 extending through the channel connection pattern 580 and the sacrificial layer structure 250 to expose an upper surface of the CSP 200. Hereinafter, a portion of the support layer disposed in the first opening 261 may be referred to as the support pattern 265.

The support pattern 265 may have various layouts in a plan view. In some example embodiments, a plurality of support patterns 265 may be spaced apart from each other in the second and third directions D2 and D3 on the first region I of the substrate 100.

Additionally, the support pattern 265 may on a portion of the second region II of the substrate 100 and surround the first region I of the substrate 100, and may have a shape of a rectangular ring in a plan view. Further, a plurality of support patterns 265, each of which may extend in the second direction D2, may be spaced apart from each other in the third direction D3 on the second region II of the substrate 100.

Each of the support layer 260 and the support pattern 265 may include a material having an etching selectivity with respect to the first to third sacrificial layers 220, 230 and 240, for example, polysilicon doped with n-type impurities.

The first insulation pattern 264 may be disposed on the third region III of the substrate 100, and may extend through the sacrificial layer structure 250 and the support layer 260 to contact an upper surface of the CSP 200. The first insulation pattern 264 may overlap the third lower wiring 184 in the first direction D1. The first insulation pattern 264 may include oxide (e.g., silicon oxide), or insulating nitride (e.g., silicon nitride).

The gate electrode structure may include gate electrodes, which may be formed at a plurality of levels, respectively, spaced apart from each other in the first direction D1 on the support layer 260 and the support pattern 265, and each of the gate electrodes may extend in the second direction D2.

In some example embodiments, the gate electrode structure may include first and second gate electrodes 600 and 650 sequentially stacked in the first direction D1. The first gate electrodes 600 may be disposed at a plurality of levels, respectively, and the second gate electrode 650 may be disposed at a single level or a plurality of second gate electrodes 650 may be disposed at a plurality of levels, respectively.

In some example embodiments, ones of the first gate electrodes 600 may serve as a ground selection line (GSL), other ones of the first gate electrodes 600 may serve as a word line, and still other ones of the first gate electrodes 600 may serve as a GIDL gate electrode, which may be used for erasing data stored in the first memory channel structure 550 using a gate induced drain leakage (GIDL) phenomenon.

For example, a lowermost one of the first gate electrodes 600 and one of the first gate electrodes 600 at a second level from below among the gate electrodes 600 may serve as the GSL, one of the first gate electrodes 600 at a third level from below among the gate electrodes 600 may be the GIDL gate electrode, and ones of the first gate electrodes 600 at other levels may serve as the word lines, respectively.

The second gate electrode 650 may serve as a string selection line (SSL).

The gate electrode 600 may include a gate conductive pattern and a gate barrier pattern covering a surface of the gate conductive pattern. The gate conductive pattern may include metal having a low resistance (e.g., tungsten, titanium, tantalum, platinum, etc.), and the gate barrier pattern may include metal nitride (e.g., titanium nitride, tantalum nitride, etc.).

In some example embodiments, the second gate electrode 650 may include, for example, polysilicon doped with n-type impurities.

The second insulation pattern 275 may be disposed between neighboring ones of the first gate electrodes 600 in the first direction D1 and between the first gate electrode 600 and the support layer 260 or the support pattern 265. The second insulation pattern 275 may include oxide (e.g., silicon oxide).

In some example embodiments, each of the first gate electrodes 600 included in the gate electrode structure may extend in the second direction D2 on the first and second regions I and II of the substrate 100, and lengths in the second direction D2 of the first gate electrodes 600 stacked in the first direction D1 may be substantially the same as each other. The second gate electrode 650 included in the gate electrode structure may extend in the second direction D2 on the first region I and a portion of the second region II adjacent to the first region I of the substrate 100, and a length in the second direction of the second gate electrode 650 may be less than the lengths in the second direction D2 of the first gate electrodes 600.

In some example embodiments, a thickness in the first direction D1 of each of the first gate electrodes 600 may be substantially constant in the second direction D2, and thus, a thickness in the first direction D1 of an end portion in the second direction D2 of each of the first gate electrodes 600 may be substantially the same as thicknesses in the first direction D1 of other portions thereof.

In some example embodiments, a plurality of gate electrode structures may be spaced apart from each other in the third direction D3. The first to third mold layers may be disposed on the third region III of the substrate 100, and may contact each of the gate electrode structures.

For example, the first to third mold layers may be sequentially stacked in the first direction D1, and each of the first to third mold layers may include a second insulation layers 270 and fourth sacrificial layers 280 alternately and repeatedly stacked in the first direction D1. The first spacer 305 may be interposed between the first and second mold layers, and the second spacer 375 and the third insulating interlayer 390 may be interposed between the second and third mold layers.

In some example embodiments, each of the second insulation layers 270 may be disposed at the same level as a corresponding one of the second insulation patterns 275, and may contact a sidewall of the corresponding one of the second insulation patterns 275. Each of the fourth sacrificial layers 280 may be disposed at the same level as a corresponding one of the first gate electrodes 600, and may contact a sidewall of the second blocking pattern 590.

The second insulation pattern 275 may include oxide (e.g., silicon oxide), and the fourth sacrificial layer 280 may include insulating nitride (e.g., silicon nitride).

In some example embodiments, the first division pattern 610 may extend in the second direction D2 on the CSP 200 on the first and second regions I and II of the substrate 100, and may divide the first gate electrodes 600 included in neighboring ones, respectively, of the gate electrode structures in the third direction D3.

In some example embodiments, the first division pattern 610 may extend through the third to sixth insulating interlayers 390, 470, 560 and 630, the etch stop layer 640, the first and second gate electrodes 600 and 650, the support layer 260, the support pattern 265 and the sacrificial layer structure 250. In some example embodiments, the first division patterns 610 may be spaced apart from each other in the third direction D3 by a constant distance.

In some example embodiments, each of the gate electrode structures divided by the first division pattern 610 and the first and second memory channel structures 550 and 720 extending through each of the gate electrode structures may collectively form a memory block, and a plurality of memory blocks may be arranged in the third direction D3.

The second division pattern 615 may be disposed between neighboring ones of the first division patterns 610 in the third direction D3, and may extend through the third to sixth insulating interlayers 390, 470, 560 and 630, the etch stop layer 640, the first and second gate electrodes 600 and 650, the support layer 260, the support pattern 265 and the sacrificial layer structure 250. In some example embodiments, a plurality of second division patterns 615 may be spaced apart from each other in the second direction D2.

The third division pattern 660 may extend in the second direction D2 on the first region I and a portion of the second region II adjacent to the first region I of the substrate 100, and may extend through the second gate electrode 650 and the etch stop layer 640 to contact an upper surface of the sixth insulating interlayer 630. In some example embodiments, the third division pattern 660 may be disposed between neighboring ones of the first and second division patterns 610 and 615.

Each of the first to third division patterns 610, 615 and 660 may include oxide (e.g., silicon oxide), or insulating nitride (e.g., silicon nitride).

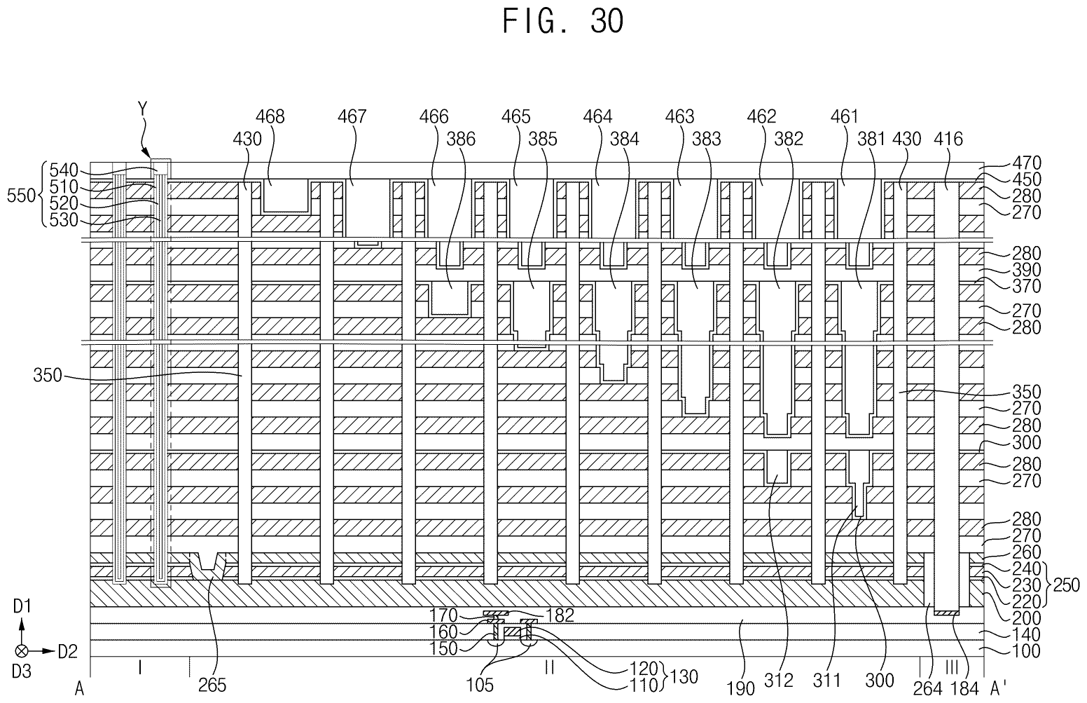

Referring to FIGS. 9 to 12 together with FIG. 30, the first memory channel structure 550 may be disposed on the first region I of the substrate 100 to contact the upper surface of the CSP 200, and may extend through the channel connection pattern 580, the support layer 260, the first gate electrodes 600, the second insulation pattern 275, and the third and fourth insulating interlayers 390 and 470 in each of the memory blocks.

In some example embodiments, the first memory channel structure 550 may include a first filling pattern 530, which may extend in the first direction D1 and have a pillar shape, a first channel 520, which may cover a sidewall and a lower surface of the first filling pattern 530 and have a cup shape, a first charge storage structure 510 on an outer sidewall and a lower surface of the first channel 520, and a first capping pattern 540 contacting upper surfaces of the first channel 520, the first filling pattern 530 and the first charge storage structure 510.

The first charge storage structure 510 may include a first tunnel insulation pattern 500, a first charge storage pattern 490 and a first blocking pattern 480 sequentially stacked in the horizontal direction from the outer sidewall of the first channel 520.

In some example embodiments, a plurality of first memory channel structures 550 may be spaced apart from each other in the second and third directions D2 and D3 in each of the memory blocks on the first region I of the substrate 100 to form a first memory channel structure array, and the plurality of first memory channel structures 550 included in the first memory channel structure array may be connected to each other by the channel connection pattern 580. For example, the first charge storage structure 510 may not be formed on a portion of the outer wall of each of the first channels 520, and the channel connection pattern 580 may contact the outer sidewall of the first channels 520 to electrically connect the first channels 520 to each other.

The first and second support structures 350 and 430 may be stacked in the first direction D1 on the second region II of the substrate 100, and may contact the upper surface of the CSP 200. The first and second support structures 350 and 430 may extend in the first direction D1 through the sacrificial layer structure 250, the first gate electrodes 600, the second insulation pattern 275 and the third insulating interlayer 390. In some example embodiments, a plurality of first support structures 350 may be spaced apart from each other in the second and third directions D2 and D3 on the second region II of the substrate 100, and a plurality of second support structures 430 may be spaced apart from each other in the second and third directions D2 and D3 on the second region II of the substrate 100.

Each of the first and second support structures 350 and 430 may include oxide (e.g., silicon oxide), and in some example embodiments, the first and second support structures 350 and 430 may include substantially the same material to be merged with each other (e.g., to form an integral structure).

The second memory channel structure 720 may include a second filling pattern 700, a second channel 690, a second charge storage structure 680 and a second capping pattern 710, which may correspond to the first memory channel structure 550. In some example embodiments, the second memory channel structure 720 may extend through the sixth insulating interlayer 630, the etch stop layer 640 and the second gate electrode 650 to at least partially contact an upper surface of the first memory channel structure 550.

In some example embodiments, the second channel 690 may include a lower portion extending through the sixth insulating interlayer 630 and having a first width, a central portion extending through the etch stop layer 640 and having a second width, and an upper portion extending through a portion of the second gate electrode 650 and having a third width.

Each of the first and third widths may be greater than the second width. The upper portion of the second channel 690 may have a cup shape, and the second filling pattern 700 may fill a space formed by the upper portion of the second channel 690.

The second charge storage structure 680 may extend through the second gate electrode 650 to cover a sidewall and a lower surface of an edge portion of the upper portion of the second channel 690, and a sidewall of the second capping pattern 710. The second charge storage structure 680 may include a second tunnel insulation pattern, a second charge storage pattern and a third blocking pattern sequentially stacked in the horizontal direction from an outer sidewall of the second channel 690, which may correspond to the first charge storage structure 510.

The second capping pattern 710 may contact upper surfaces of the upper portion of the second channel 690 and the second filling pattern 700, and may also contact an inner sidewall of the second charge storage structure 680.

In some example embodiments, the second memory channel structure 720 may contact a corresponding one of the first memory channel structures 550, so that a plurality of second memory channel structures 720 may be spaced apart from each other in the second and third directions D2 and D3 in each of the memory blocks on the first region I of the substrate 100 to form a second memory channel structure array.

The first and second channels 520 and 690 may include, for example, undoped polysilicon, the first and second filling patterns 530 and 700 may include oxide (e.g., silicon oxide), and the first and second capping patterns 540 and 710 may include, for example, polysilicon doped with impurities.

The first tunnel insulation pattern 500 and the second tunnel insulation pattern may include oxide (e.g., silicon oxide), the first charge storage pattern 490 and the second charge storage pattern may include nitride (e.g., silicon nitride), and the first blocking pattern 480 and the third blocking pattern may include a oxide (e.g., silicon oxide).

The second blocking pattern 590 may cover upper and lower surfaces of each of the first gate electrodes 600 and a sidewall of each of the first gate electrodes 600 that may face the first memory channel structure 550, the first and second support structures 350 and 430, and the first to eighth upper contact plugs 761, 762, 763, 764, 765, 766, 767 and 768. The second blocking pattern 590 may include metal oxide (e.g., aluminum oxide or hafnium oxide).

The third insulating interlayer 390 may be disposed between lower ones of the first gate electrodes 600 and upper ones of the first gate electrodes 600 in the gate electrode structure, and the fourth insulating interlayer 470 may be disposed between an uppermost one of the first gate electrodes 600 and the second gate electrode 650 in the gate electrode structure.

The fifth and sixth insulating interlayers 560 and 630 may be disposed on the fourth insulating interlayer 470. The fifth insulating interlayer 560 may be disposed on the fourth insulating interlayer 470. The fifth insulating interlayer 560 may be disposed on the second region II of the substrate 100, and the sixth insulating interlayer 630 may be disposed on the first region I of the substrate 100.

The etch stop layer 640 and the second gate electrode 650 may be sequentially stacked on the sixth insulating interlayer 630.

The seventh insulating interlayer 730 may be disposed on the fifth insulating interlayer 560 and the second gate electrode 650, and the eighth to tenth insulating interlayers 770, 800 and 840 may be sequentially stacked on the seventh insulating interlayer 730.

Each of the first to fifth insulating interlayers 140, 190, 390, 470 and 560, each of the seventh to tenth insulating interlayers 730, 770, 800 and 840 and the etch stop layer 640 may include oxide (e.g., silicon oxide), some of which may be merged with each other. The sixth insulating interlayer 630 may include insulating nitride (e.g., silicon nitride).

Each of the first to eighth upper contact plugs 761, 762, 763, 764, 765, 766, 767 and 768 may extend through the fourth, fifth and seventh insulating interlayers 470, 560 and 730, a portion of the gate electrode structure and the second blocking pattern 590 on the second region II of the substrate 100, and may contact an upper surface of a corresponding one of the first gate electrodes 600 in the gate electrode structure to be electrically connected thereto.

That is, each of the first to eighth upper contact plugs 761, 762, 763, 764, 765, 766, 767 and 768 may contact an upper surface of a corresponding one of the first gate electrodes 600 in the gate electrode structure, and may extend through ones of the first gate electrodes 600 over the corresponding one of the first gate electrodes 600. However, each of the first to eighth upper contact plugs 761, 762, 763, 764, 765, 766, 767 and 768 may be electrically insulated from the ones of the first gate electrodes 600, which are disposed over the corresponding one of the first gate electrodes 600, by the first to third spacers 305, 375 and 455.

In some example embodiments, the second support structures 430 may be disposed at respective vertices of a rectangle in a plan view. In some example embodiments, the first to eighth upper contact plugs 761, 762, 763, 764, 765, 766, 767 and 768 may be spaced apart from each other in the second direction D2 on the second region II of the substrate 100.

The first gate electrodes 600 included in the gate electrode structure may have substantially the same lengths in the second direction D2, and thus each of upper contact plugs except for the first upper contact plug 761 that is closest to the third region III of the substrate 100 among the first to eighth upper contact plugs 761, 762, 763, 764, 765, 766, 767 and 768, that is, each of the second to eighth upper contact plugs 762, 763, 764, 765, 766, 767 and 768 may contact an upper surface of a portion of a corresponding one of the first gate electrodes 600 that is not an end portion thereof.

In some example embodiments, each of the first to eighth upper contact plugs 761, 762, 763, 764, 765, 766, 767 and 768 may include an upper portion extending through the fourth, fifth and seventh insulating interlayers 470, 560 and 730 and a lower portion extending partially through the gate electrode structure under the upper portion, and a lower surface of the upper portion may have a width smaller than a width of an upper surface of the lower portion.

The lower portion of each of the first to sixth upper contact plugs 761, 762, 763, 764, 765 and 766 may include a first lower portion lower than a lower surface of the third insulating interlayer 390 and a second lower portion substantially coplanar with or higher than the lower surface of the third insulating interlayer 390.

In some example embodiments, each of the first to sixth upper contact plugs 761, 762, 763, 764, 765 and 766 may include a portion in which a width decreases in a stepwise manner from a top toward a bottom thereof in the first direction D1. In some example embodiments, a width of an upper surface of the first lower portion of each of the first to sixth upper contact plugs 761, 762, 763, 764, 765 and 766 may be greater than a width of a lower surface of the second lower portion.

In some example embodiments, the first to third spacers 305, 375 and 455 may be disposed on a sidewall of the lower portion of each of the first to eighth upper contact plugs 761, 762, 763, 764, 765, 766, 767 and 768, and may contact sidewalls of the second blocking pattern 590 and the second insulation pattern 275.

For example, the third spacer 455 may be disposed on the sidewall of the lower portion of each of the seventh and eighth upper contact plugs 767 and 768. Additionally, the third spacer 455 may be disposed on the sidewall of the second lower portion of each of the first to sixth upper contact plugs 761, 762, 763, 764, 765 and 766, and the second spacer 375 may be disposed on the sidewall of the first lower portion of each of the first to sixth upper contact plugs 761, 762, 763, 764, 765 and 766. In some example embodiments, the second and third spacers 375 and 455 may not contact each other.

The first spacer 305 may be disposed under a portion of the second lower portion of each of the first and second upper contact plugs 761 and 762. The first spacer 305 may be disposed under the second spacer 375, and may not contact the second spacer 375.

The first spacer 305 may also be disposed on an upper surface of an uppermost one of the fourth sacrificial layers 280 included in the first mold layer and an upper surface of the second blocking pattern 590 contacting the uppermost one of the fourth sacrificial layers 280 in the first mold layer, the second spacer 375 may also be disposed on an upper surface of an uppermost one of the fourth sacrificial layers 280 included in the second mold layer and an upper surface of the second blocking pattern 590 contacting the uppermost one of the fourth sacrificial layers 280 in the second mold layer, and the third spacer 455 may also be disposed on an upper surface of an uppermost one of the fourth sacrificial layers 280 included in the third mold layer and an upper surface of the second blocking pattern 590 contacting the uppermost one of the fourth sacrificial layers 280 in the third mold layer.;

Each of the first to third spacers 305, 375 and 455 may include oxide (e.g., silicon oxide), and thus, in some example embodiments, may be merged (e.g., may form an integral body) with the second insulation pattern 275 or the third and fourth insulating interlayers 390 and 470.

FIGS. 10 to 12 shows the first to eighth upper contact plugs 761, 762, 763, 764, 765, 766, 767 and 768 as upper contact plugs that may partially extend through the gate electrode structure to contact a single first gate electrode 600 in the gate electrode structure, however, the inventive concepts may not be limited thereto, and the semiconductor device may include more than eighth upper contact plugs.

The ninth upper contact plug 769 may extend through the seventh insulating interlayer 730 to contact an upper surface of the second gate electrode 650. In some example embodiments, the ninth upper contact plug 769 may be disposed on a portion of the second region II adjacent to the first region I of the substrate 100. In some example embodiments, the ninth upper contact plug 769 may be disposed between neighboring ones of the first and third division patterns 610 and 660 in the third direction D3 and between neighboring ones of the second and third division patterns 615 and 660 in the third direction D3.

The through via 790 may extend in the first direction D1 on the third region III of the substrate 100, and may extend through an upper portion of the second insulating interlayer 190, the first insulation pattern 264, the first to third mold layers, and the third, fourth, fifth, seventh and eighth insulating interlayers 390, 470, 560, 730 and 770 to contact an upper surface of the third lower wiring 184.

The first upper via 810 may extend through the seventh to ninth insulating interlayers 730, 770 and 800 to contact an upper surface of the second memory channel structure 720, each of the second upper vias 820 may extend through the eighth and ninth insulating interlayers 770 and 800 to contact an upper surface of a corresponding one of the first to eighth upper contact plugs 761, 762, 763, 764, 765, 766, 767 and 768, the third upper via 825 may extend through the eighth and ninth insulating interlayers 770 and 800 to contact an upper surface of the ninth upper contact plug 769, and the fourth upper via 830 may extend through the ninth insulating interlayer 800 to contact an upper surface of the through via 790.

The first to fourth upper wirings 850, 860, 865 and 870 may extend through the tenth insulating interlayer 840 to contact upper surfaces of the first to fourth upper vias 810, 820, 825 and 830, respectively.

In some example embodiments, the first upper wiring 850 may extend in the third direction D3, and a plurality of first upper wirings 850 may be spaced apart from each other in the second direction D2. The first wiring 850 may serve as a bit line.

FIGS. 10 to 12 shows the first to fourth upper wirings 850, 860, 865 and 870 and the first to fourth vias 810, 820, 825 and 830 as upper wirings and upper vias, respectively, however, the inventive concepts may not be limited thereto. Thus, the upper wirings and the upper vias may have various layouts, and the semiconductor device may further include upper wirings and/or upper vias at upper levels.

Each of the first to ninth upper contact plugs 761, 762, 763, 764, 765, 766, 767, 768 and 769, the through via 790, the first to fourth upper vias 810, 820, 825 and 830, and the first to fourth upper wirings 850, 860, 865 and 870 may include a conductive material, for example, metal, metal nitride, metal silicide, etc.

The semiconductor device may include the gate electrode structure having the first gate electrodes 600 stacked in the first direction D1 and the second gate electrode 650 over the uppermost one of the first gate electrodes 600, the first to eighth upper contact plugs 761, 762, 763, 764, 765, 766, 767 and 768 contacting the upper surfaces of the first gate electrodes 600, respectively, and the ninth upper contact plug contacting the upper surface of the second gate electrode 650.

Each of the first gate electrodes 600 may extend in the second direction D2, and may have a constant thickness. The first gate electrodes 600 may have substantially the same length in the second direction D2. Thus, the gate electrode structure may not have a staircase shape, and thus the formation of the gate electrode structure may be simplified.

Each of the first to eighth upper contact plugs 761, 762, 763, 764, 765, 766, 767 and 768 for transferring electrical signals to the first gate electrodes 600 included in the gate electrode structure not having a staircase shape may contact an upper surface of a corresponding one of the first gate electrodes 600, and may extend through ones of the first gate electrodes 600 over the corresponding one of the first gate electrodes 600. The first to third spacers 305, 375 and 455 may be disposed between each of the first to eighth upper contact plugs 761, 762, 763, 764, 765, 766, 767 and 768 and the ones of the first gate electrodes 600 over the corresponding one of the first gate electrodes 600 so that each of the first to eighth upper contact plugs 761, 762, 763, 764, 765, 766, 767 and 768 may be electrically insulated from the ones of the first gate electrodes 600 over the corresponding one of the first gate electrodes 600.

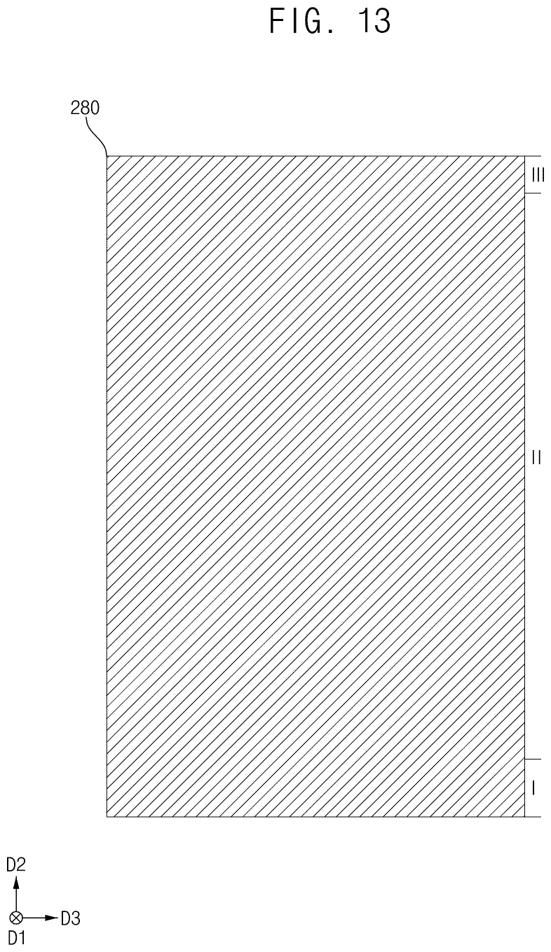

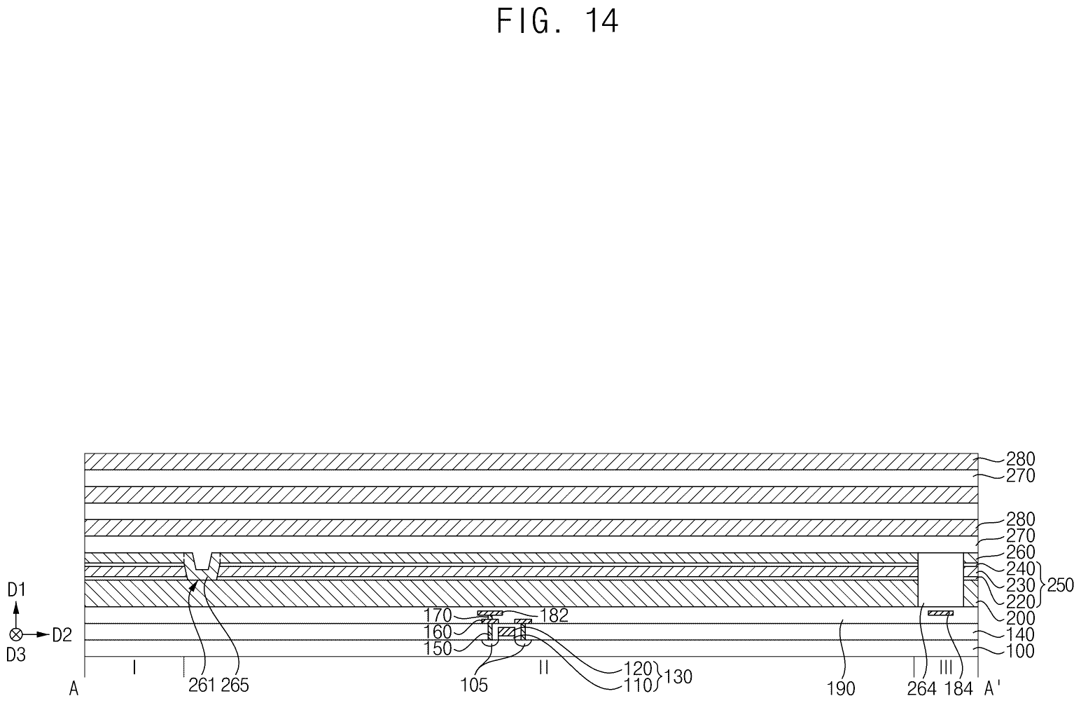

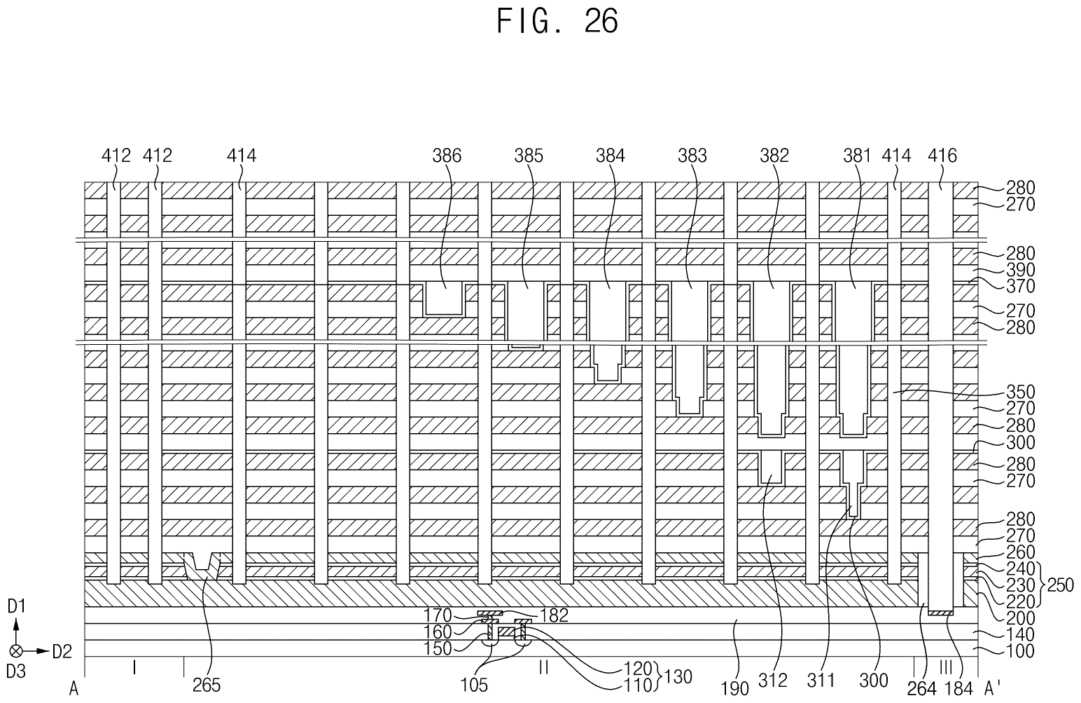

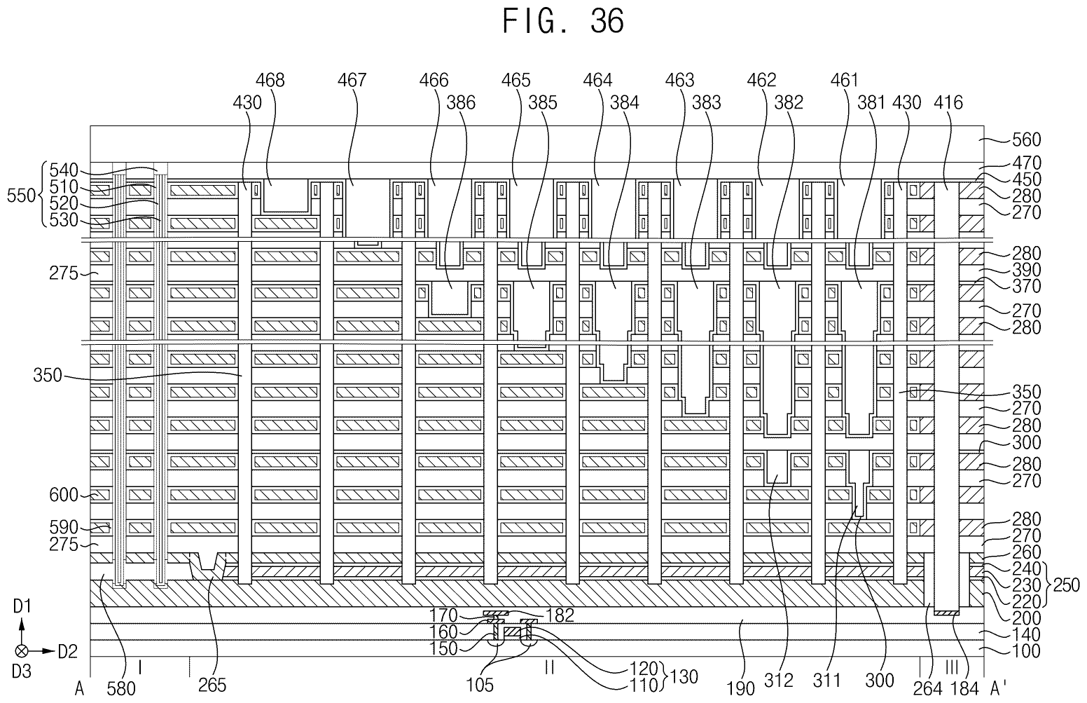

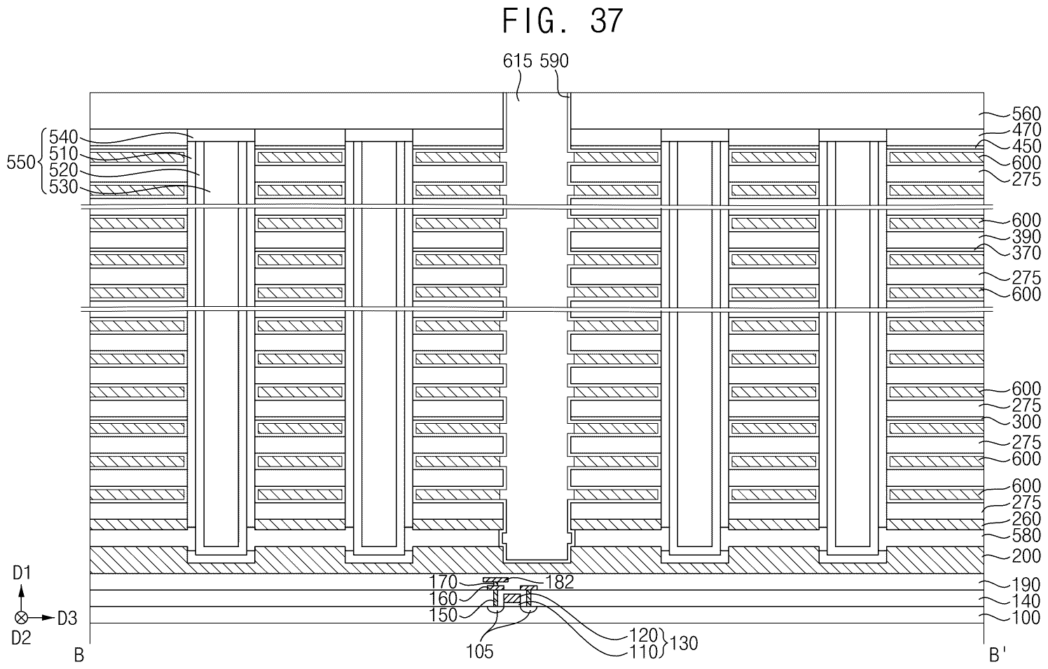

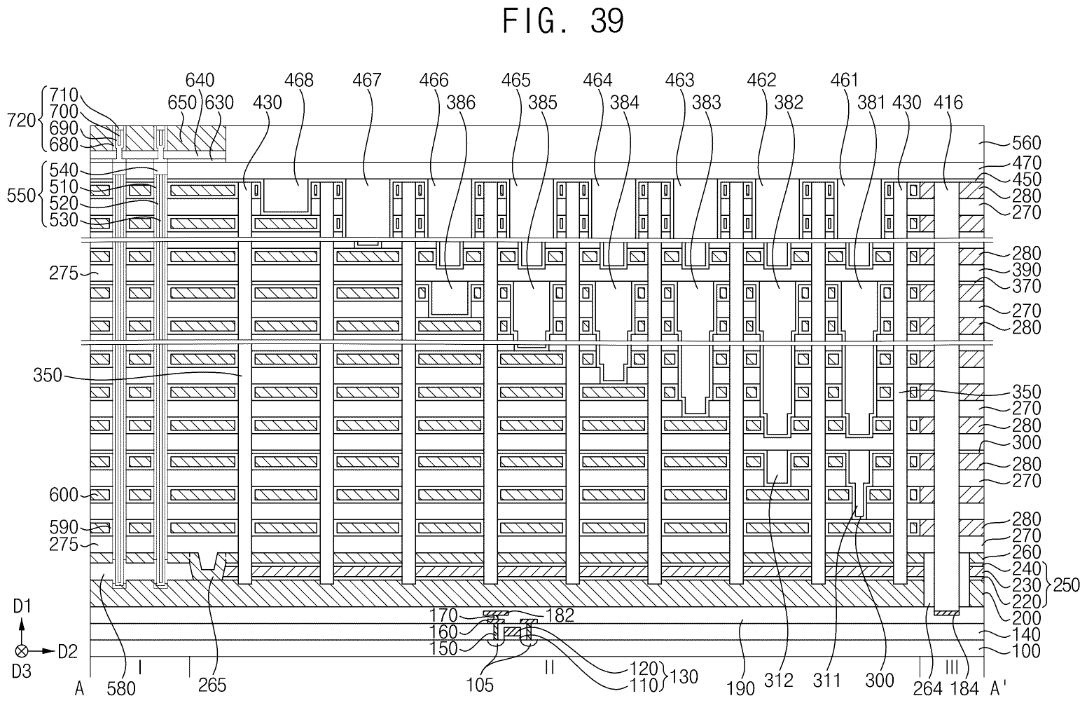

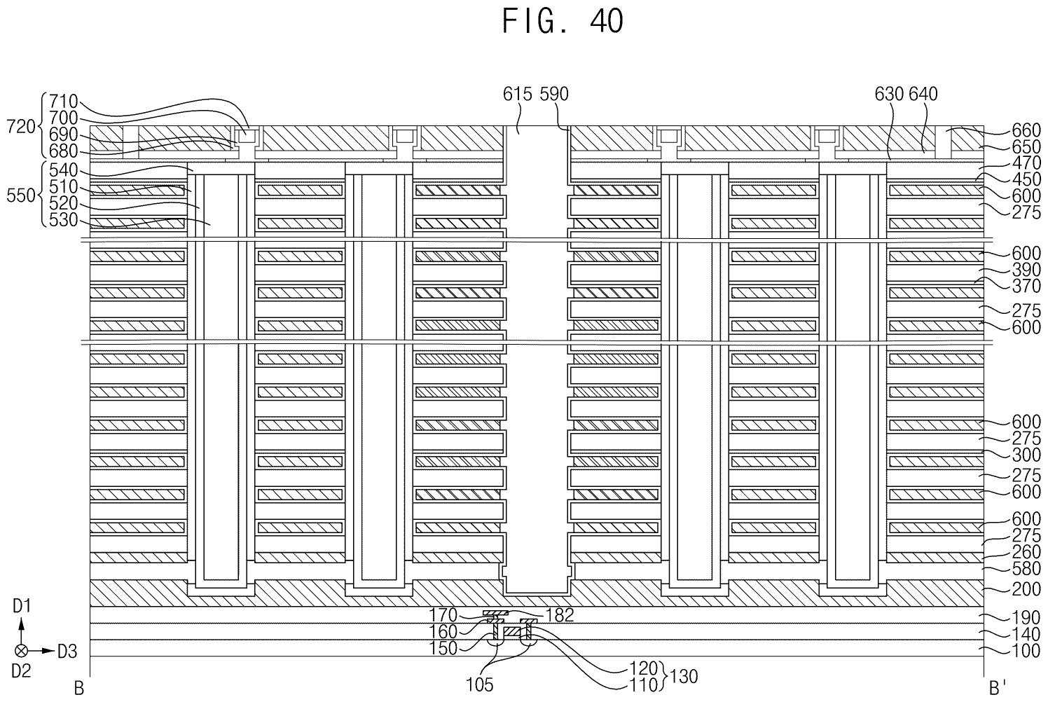

FIGS. 13 to 46 are plan views and cross-sectional views illustrating a method of manufacturing a semiconductor device. Particularly, FIGS. 13, 15, 19, 22, 27, 32, 35 and 38 are the plan views, and FIGS. 14, 16-18, 20-21, 23-26, 28-31, 33-34, 36-37 and 39-46 are the cross-sectional views.

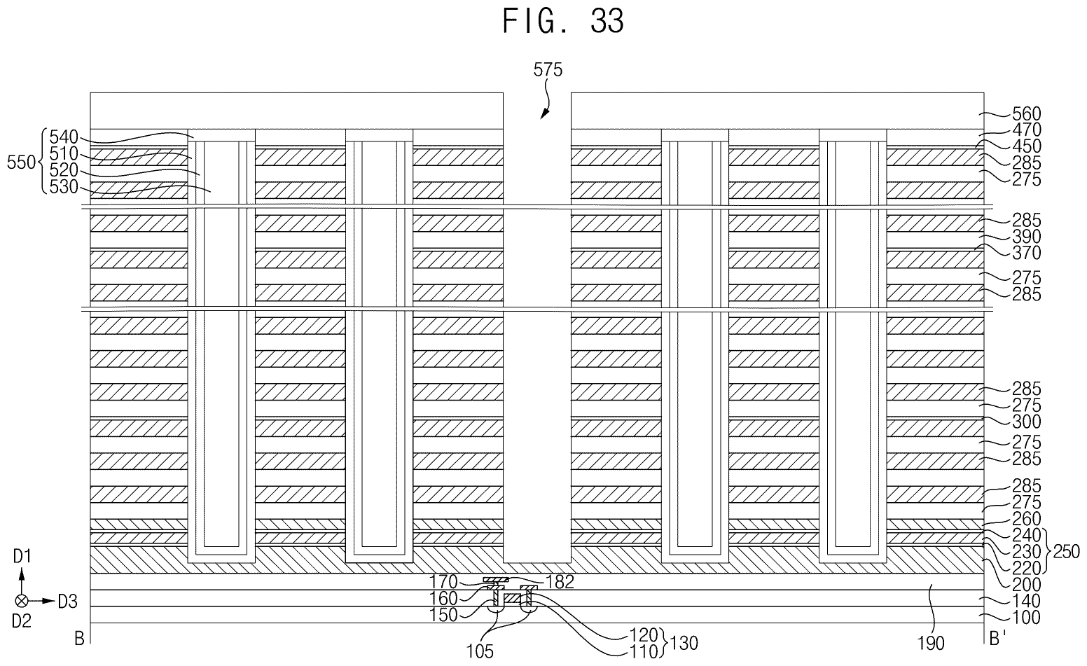

FIGS. 14, 16-18, 20-21, 23-26, 28-31, 36, 39 and 41-46 are cross-sectional views taken along lines A-A′ of corresponding plan views, respectively, and FIGS. 33-34, 37 and 40 are cross-sectional views taken along lines B-B′ of corresponding plan views.

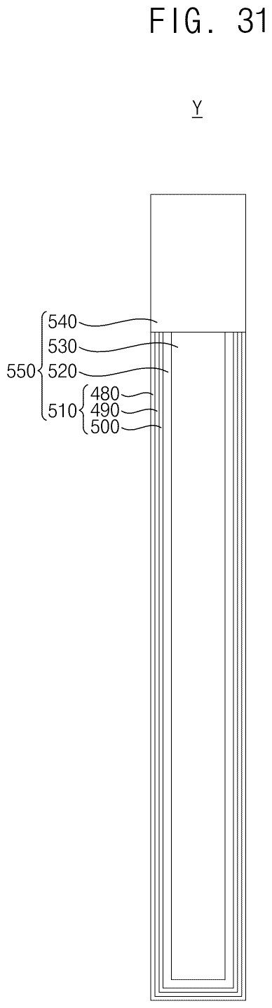

FIGS. 13 to 46 are drawings of region X of FIG. 9, and FIG. 31 is an enlarged cross-sectional view of region Y of FIG. 30.

Referring to FIGS. 13 and 14, a lower circuit pattern may be formed on a substrate 100, and first and second insulating interlayers 140 and 190 may be sequentially stacked on the substrate 100 to cover the lower circuit pattern.

Each element of the lower circuit pattern may be formed by a patterning process or a damascene process.

A CSP 200 and a sacrificial layer structure 250 may be sequentially formed on the second insulating interlayer 190, the sacrificial layer structure 250 may be partially removed to form a first opening 261 exposing an upper surface of the CSP 200, and a support layer 260 may be formed on an upper surface of the sacrificial layer structure 250 and the exposed upper surface of the CSP 200.

The sacrificial layer structure 250 may include first, second and third sacrificial layers 220, 230 and 240 sequentially stacked. Each of the first and third sacrificial layers 220 and 240 may include oxide (e.g., silicon oxide), and the second sacrificial layer 230 may include nitride (e.g., silicon nitride).

The support layer 260 may include a material having an etching selectivity with respect to the first to third sacrificial layers 220, 230 and 240, for example, polysilicon doped with n-type impurities. The support layer 260 may be conformally formed, and thus a first recess may be formed on a portion of the support layer 260 in the first opening 261. Hereinafter, the portion of the support layer 260 in the first opening 261 may contact the upper surface of the CSP 200 and may be referred to as a support pattern 265.

The support pattern 265 may have various layouts in a plan view. For example, a plurality of support patterns 265 may be spaced apart from each other in the second and third directions D2 and D3 on the first region I of the substrate 100. Additionally, the support pattern 265 may extend in the third direction D3 on a portion of the second region II adjacent to the first region I of the substrate 100. Furthermore, a plurality of support patterns 265, each of which may extend in the second direction D2, may be spaced apart from each other in the third direction D3 on the second region II of the substrate 100. FIG. 14 shows the support pattern 265 extending in the third direction D3 on the portion of the second region II adjacent to the first region I of the substrate 100.

A first insulation pattern 264 may be formed partially through the CSP 200, the sacrificial layer structure 250 and the support layer 260 on the third region III of the substrate 100. In some example embodiments, the first insulation pattern 264 may overlap the third lower wiring 184 in the first direction D1.

A second insulation layer 270 and a fourth sacrificial layer 280 may be alternately and repeatedly stacked in the first direction D1 on the support layer 260, the support pattern 265 and the first insulation pattern 264, and thus a first mold layer including the second insulation layers 270 and the fourth sacrificial layers 280 may be formed. In an example embodiment, the first mold layer may include three second insulation layers 270 and three fourth sacrificial layers 280 stacked in the first direction D1, however, the inventive concepts may not be limited thereto.

The second insulation layer 270 may include oxide (e.g., silicon oxide), and the fourth sacrificial layer 280 may include a material having an etching selectivity with respect to the second insulation layer 270, for example, a nitride such as silicon nitride.

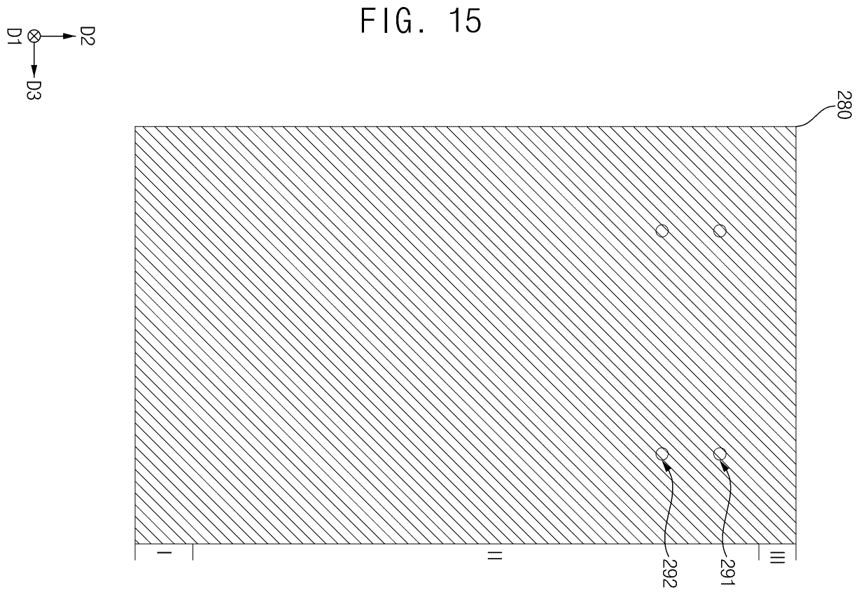

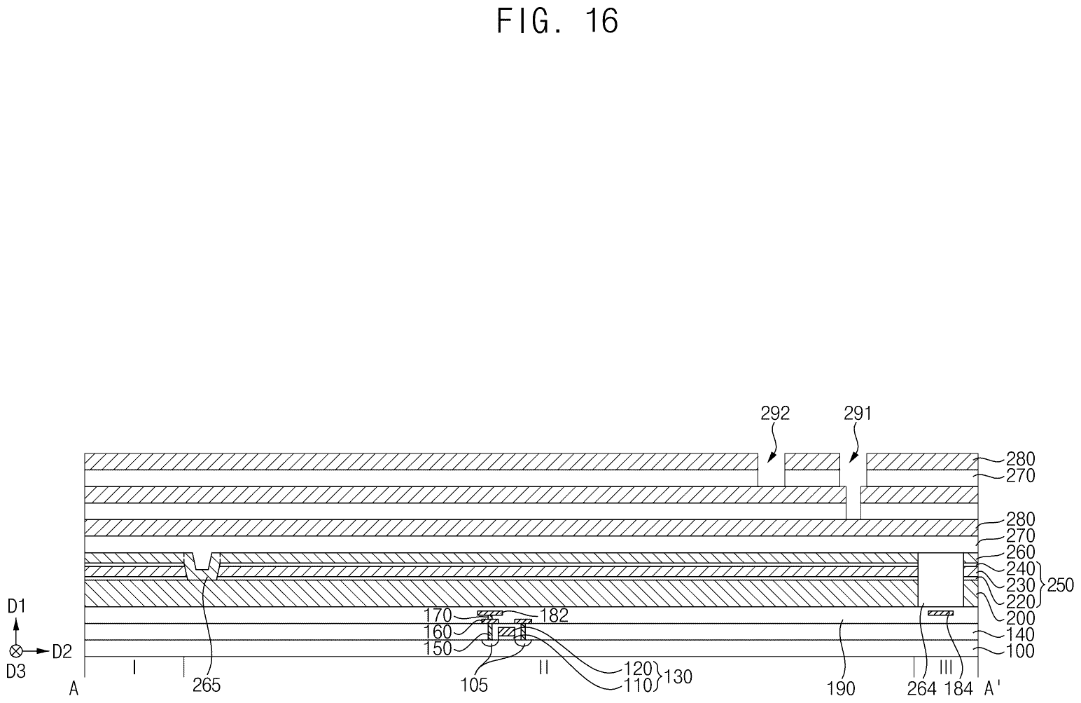

Referring to FIGS. 15 and 16, the first mold layer on the second region II of the substrate 100 may be partially removed to form twenty-first and twenty-second holes 291 and 292 exposing an upper surface of one of the fourth sacrificial layers 280 at a third level from above among the fourth sacrificial layers 280 and an upper surface of one of the fourth sacrificial layers 280 at a second level from above among the fourth sacrificial layers 280, respectively.

In some example embodiments, the twenty-second hole 292 may be formed by partially removing an uppermost one of the fourth sacrificial layers 280 and an uppermost one of the second insulation layers 270, and the twenty-second hole 292 may be formed by partially removing the uppermost one of the fourth sacrificial layers 280, one of the fourth sacrificial layers 280 at a second level from above, the uppermost one of the second insulation layers 270, and one of the second insulation layers 270 at a second level from above. The twenty-first hole 291 may include a lower portion having a relatively small width and an upper portion having a relatively large width.

In some example embodiments, a plurality of twenty-first holes 291 may be spaced apart from each other in the third direction D3, and a plurality of twenty-second holes 292 may be spaced apart from each other in the third direction D3.

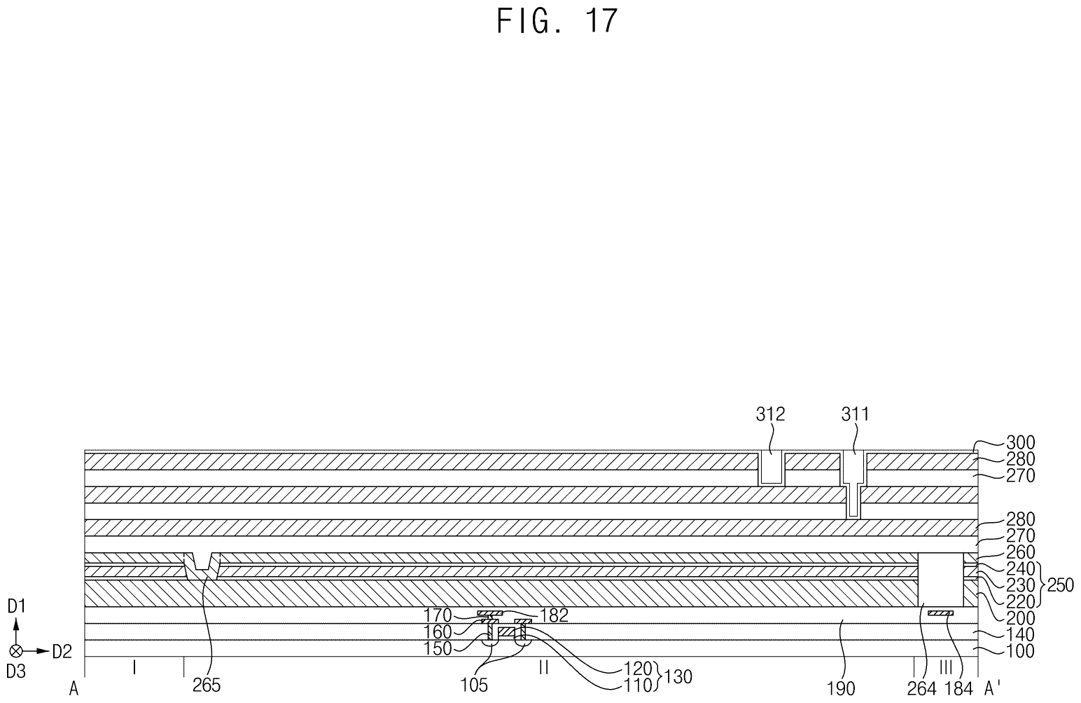

Referring to FIG. 17, a first spacer layer 300 may be formed on inner walls of the twenty-first and twenty-second holes 291 and 292 and an upper surface of the uppermost one of the fourth sacrificial layers 280, a fifth sacrificial layer may be formed on the first spacer layer 300 to fill the twenty-first and twenty-second holes 291 and 292, and a planarization process may be performed on the fifth sacrificial layer until an upper surface of a portion of the first spacer layer 300 on the uppermost one of the fourth sacrificial layers 280 is exposed to form fifth and sixth sacrificial patterns 311 and 312 in the twenty-first and twenty-second holes 291 and 292, respectively.

The planarization process may include a chemical mechanical polishing (CMP) process and/or an etch back process.

The first spacer layer 300 may include oxide (e.g., silicon oxide), and the fifth sacrificial layer may include, for example, polysilicon.

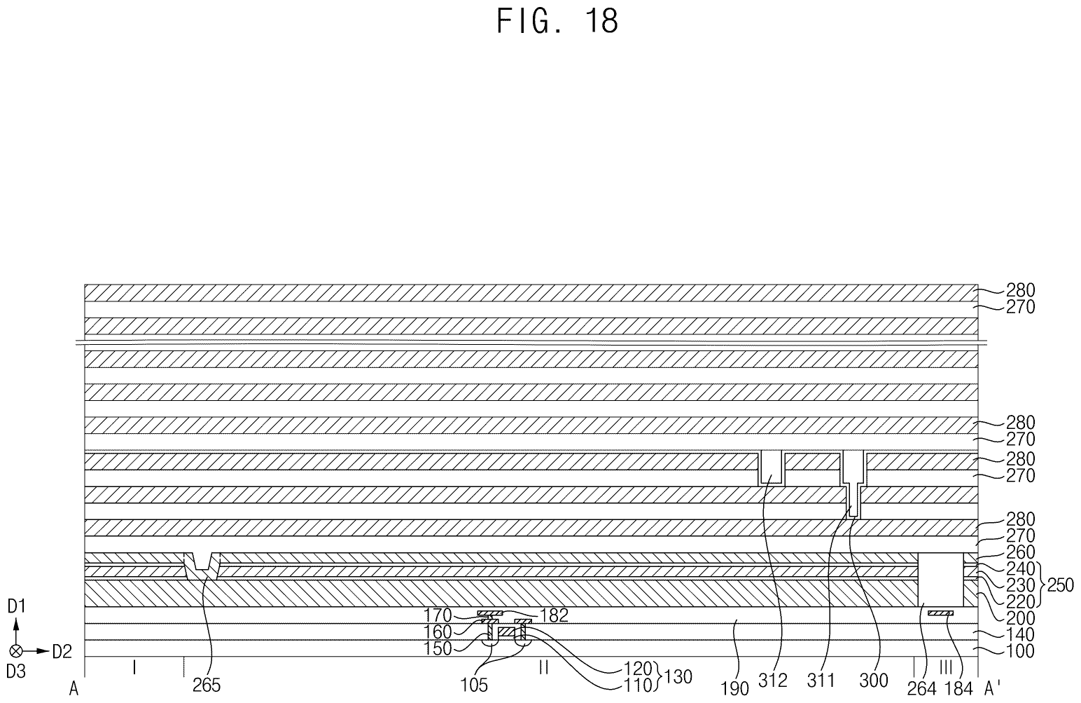

Referring to FIG. 18, the second insulation layer 270 and the fourth sacrificial layer 280 may be alternately and repeatedly stacked in the first direction D1 on the first spacer layer 300 and the fifth and sixth sacrificial patterns 311 and 312, and thus a second mold layer including the second insulation layers 270 and the fourth sacrificial layers 280.

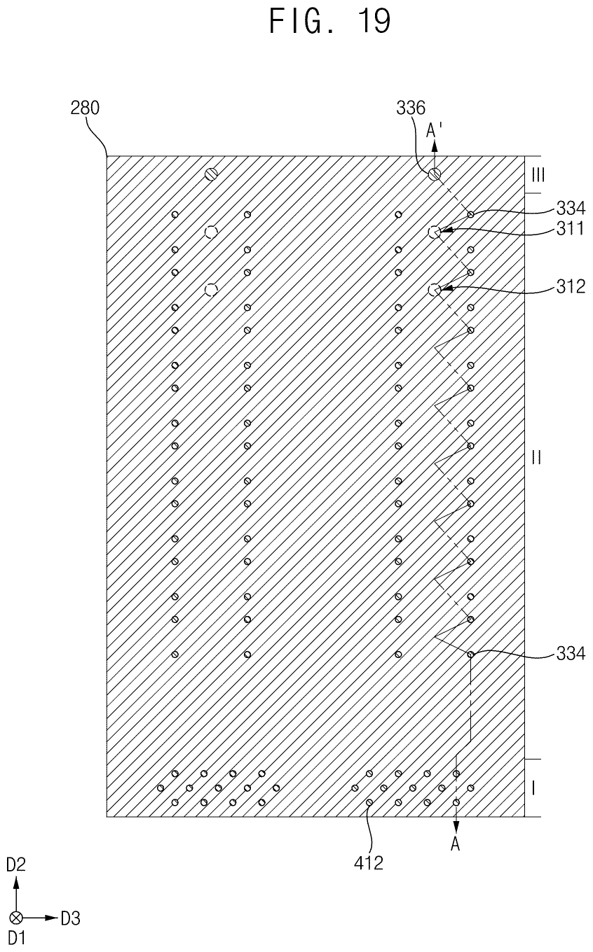

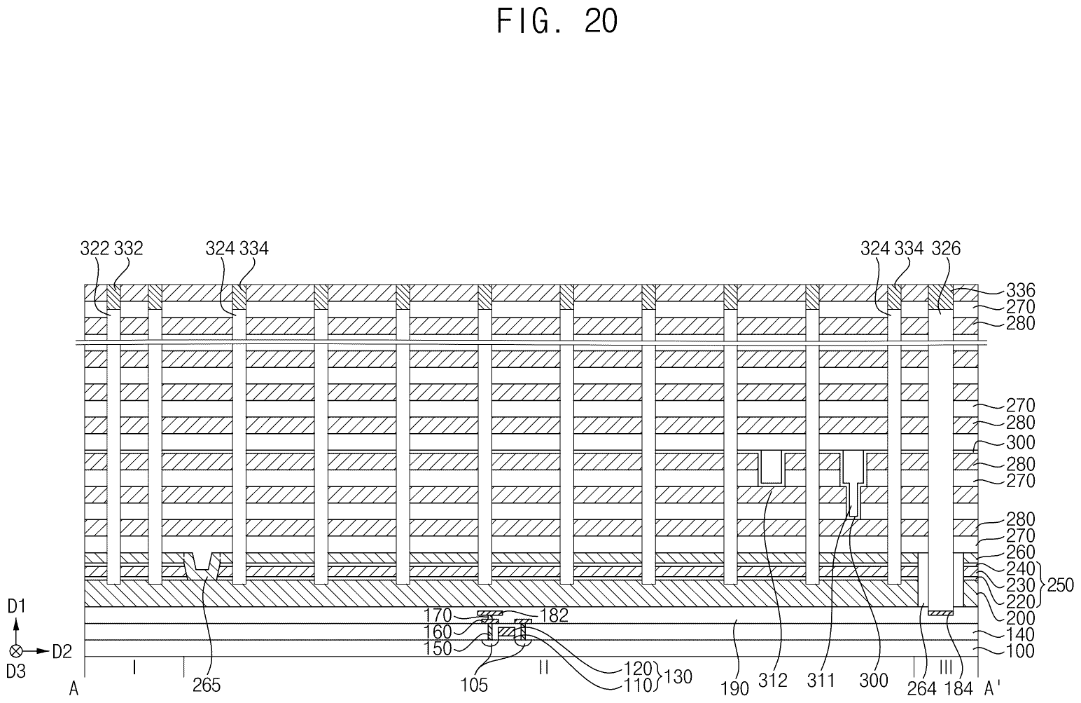

Referring to FIGS. 19 and 20, twenty-third and twenty-fourth holes may be formed through the first and second mold layers, the support layer 260 and the sacrificial layer structure 250 to expose the upper surface of the CSP 200 on the first and second regions I and II, respectively, and a twenty-fifth hole may be formed through the first and second mold layers, the first insulation pattern 264 and an upper portion of the second insulating interlayer 190 to expose an upper surface of the third lower wiring 184 on the third region III.

In some example embodiments, a plurality of twenty-third holes may be spaced apart from each other in the second and third directions D2 and D3 on the first region I of the substrate 100, and a plurality of twenty-fourth holes may be spaced apart from each other in the second and third directions D2 and D3 on the second region II of the substrate 100.

A seventh sacrificial layer may be formed on the CSP 200, the third lower wiring 184 and an uppermost one of the fourth sacrificial layers 280 of the second mold layer, and for example, a CMP process may be performed on the seventh sacrificial layer to form first to third sacrificial pillars 322, 324 and 326 in the twenty-third to twenty-fifth holes, respectively. The seventh sacrificial layer may include metal, for example, tungsten or polysilicon.

Upper portions of the first to third sacrificial pillars 322, 324 and 326 may be removed by, for example, an etch back process to form second to fourth recesses, respectively, and first to third sacrificial capping patterns 332, 334 and 336 may be formed in the second to fourth recesses, respectively. Each of the first to third sacrificial capping patterns 332, 334 and 336 may include metal nitride (e.g., titanium nitride, tantalum nitride, etc.).

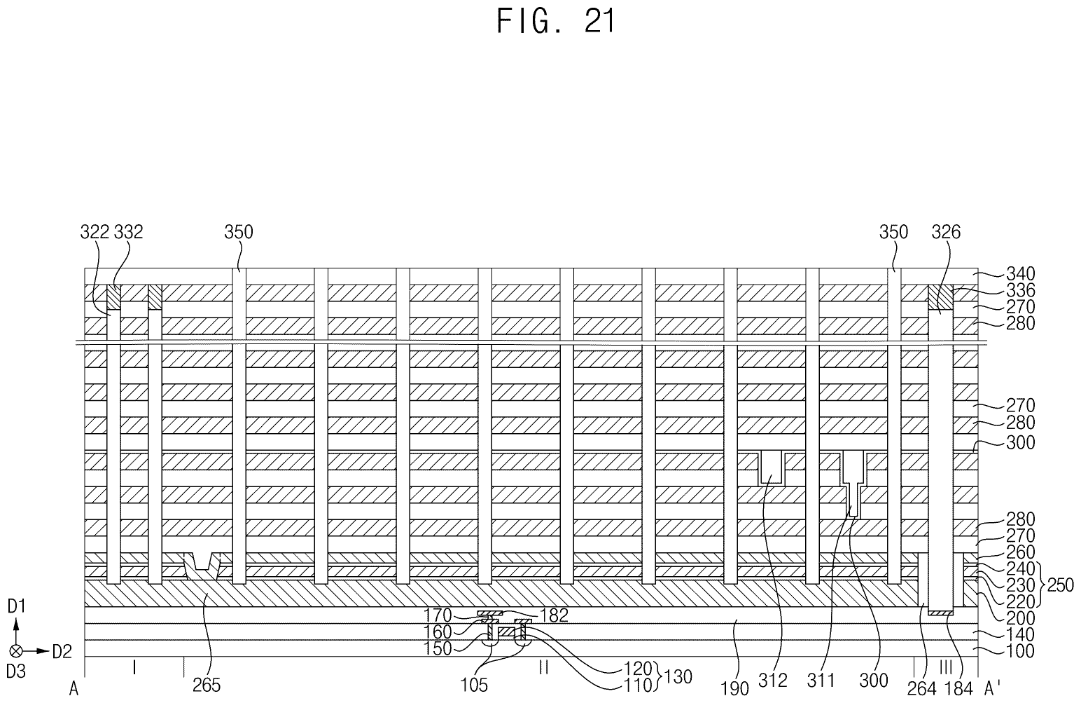

Referring to FIG. 21, a first sacrificial insulating interlayer 340 may be formed on the uppermost one of the fourth sacrificial layers 280 of the second mold layer and the first to third sacrificial capping patterns 332, 334 and 336, a twenty-sixth hole may be formed through the first sacrificial insulating interlayer 340 to expose an upper surface of the second sacrificial capping pattern 334, the second sacrificial capping pattern 334 and the second sacrificial pillar 324 may be removed to form the twenty-fourth hole again, and first support structures 350 may be formed in the twenty-fourth and twenty-sixth holes, respectively.

Each of the first sacrificial insulating interlayer 340 and the first support structure 350 may include oxide (e.g., silicon oxide).

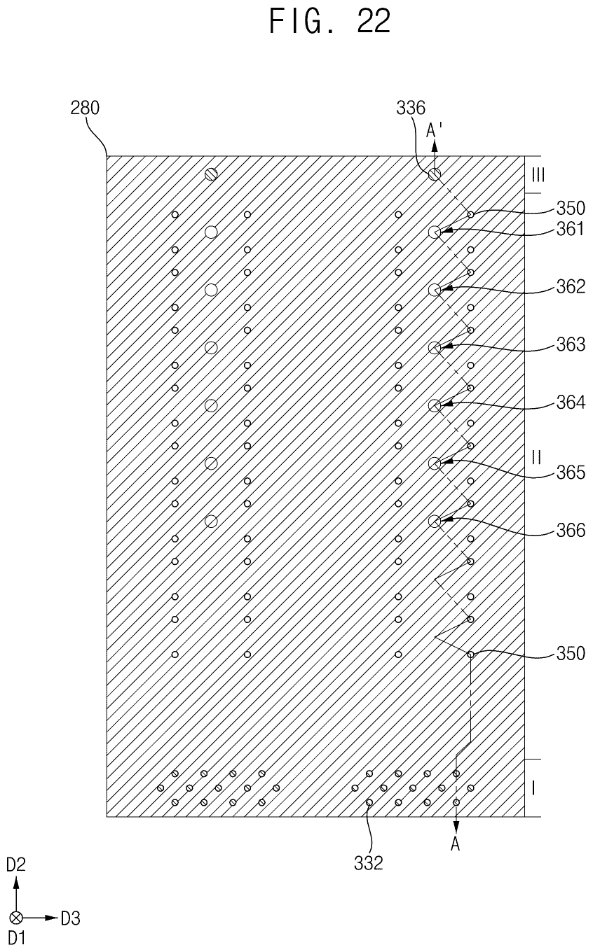

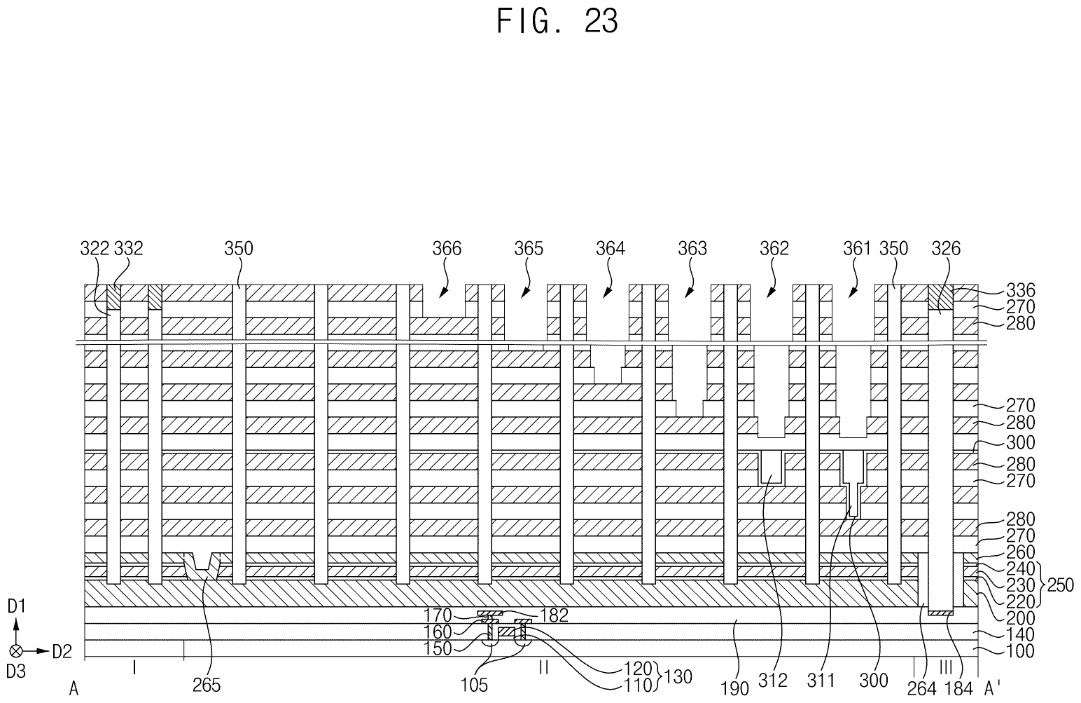

Referring to FIGS. 22 and 23, processes substantially the same as or similar to those illustrated with respect to FIGS. 1 to 8 may be performed to form twenty-seventh to thirty-second holes 361, 362, 363, 364, 365 and 366 through the first sacrificial insulating interlayer 340 and a portion of the second mold layer on the second region II of the substrate 100.

In some example embodiments, the twenty-seventh to thirty-second holes 361, 362, 363, 364, 365 and 366 may be formed to be spaced apart from each other in the second direction D2 on the second region II of the substrate 100. The twenty-seventh and twenty-eighth holes 361 and 362 may expose an upper surface of a lowermost one of the second insulation layers 270 of the second mold layer, and may overlap the fifth and sixth sacrificial patterns 311 and 312, respectively, in the first direction D1.

The twenty-ninth to thirty-second holes 363, 364, 365 and 366 may expose upper surface of corresponding ones of the fourth sacrificial layers 280, respectively. For example, the twenty-ninth hole 363 may expose an upper surface of a lowermost one of the fourth sacrificial layers 280 of the second mold layer, and the thirty-second hole 366 may expose an upper surface of one of the fourth sacrificial layers 280 at a second level from above in the second mold layer.

FIGS. 22 and 23 show six holes (e.g., twenty-seventh to thirty-second holes 361, 362, 363, 364, 365 and 366) exposing upper surfaces of the fourth sacrificial layers 280 included in the second mold layer, respectively. However, the inventive concepts may not be limited thereto, and in some example embodiments, more than six holes may be formed.

In some example embodiments, each of the twenty-seventh to thirty-second holes 361, 362, 363, 364, 365 and 366 may be formed between the first support structures 350 in a plan view. For example, the first support structures 350 may be formed at vertices of a rectangle, respectively, in a plan view, and each of the twenty-seventh to thirty-second holes 361, 362, 363, 364, 365 and 366 may be formed in an inside of the rectangle in a plan view.

By the etching process, the first sacrificial insulating interlayer 340 may be removed.

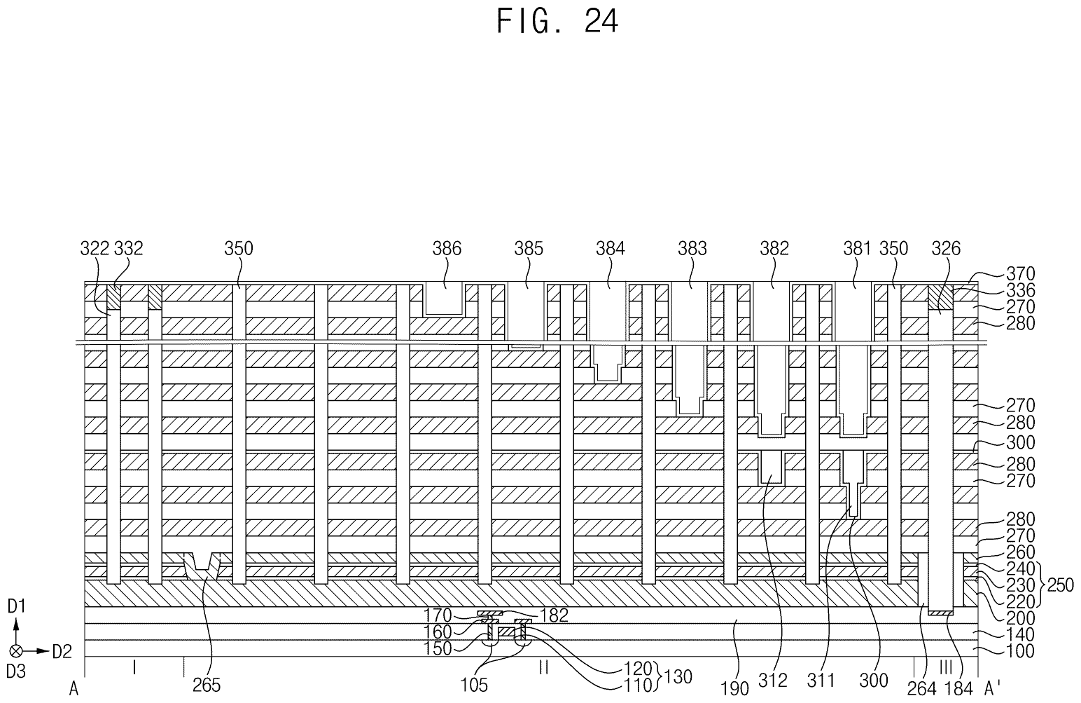

Referring to FIG. 24, a second spacer layer 370 may be formed on inner walls of the twenty-seventh to thirty-second holes 361, 362, 363, 364, 365 and 366, an upper surface of the uppermost one of the fourth sacrificial layers 280 of the second mold layer, upper surfaces of the first and third sacrificial capping patterns 332 and 336 and an upper surface of the first support structure 350, an eighth sacrificial layer may be formed on the second spacer layer 370 to fill the twenty-seventh to thirty-second holes 361, 362, 363, 364, 365 and 366, and a planarization process may be performed on the eighth sacrificial layer until an upper surface of a portion of the second spacer layer 370 on the uppermost one of the fourth sacrificial layers 280 of the second mold layer is exposed to form seventh to twelfth sacrificial patterns 381, 382, 383, 384, 385 and 386 in the twenty-seventh to thirty-second holes 361, 362, 363, 364, 365 and 366, respectively.

The second spacer layer 370 may include oxide (e.g., silicon oxide), and the eighth sacrificial layer may include, for example, polysilicon.

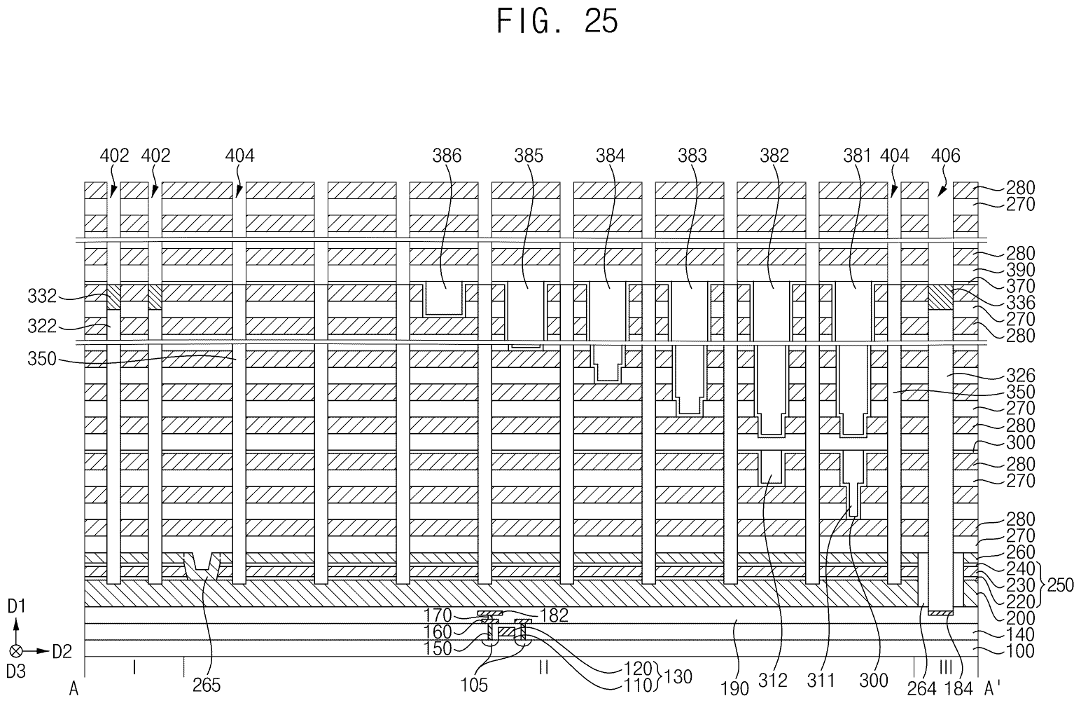

Referring to FIG. 25, a third insulating interlayer 390 may be formed on the second spacer layer 370 and the seventh to twelfth sacrificial patterns 381, 382, 383, 384, 385 and 386, and the fourth sacrificial layer 280 and the second insulation layer 270 may be alternately and repeatedly stacked on the third insulating interlayer 390 to form a third mold layer include the fourth sacrificial layers 280 and the second insulation layers 270.

The third insulating interlayer 390 may include oxide (e.g., silicon oxide).

The first and third sacrificial capping patterns 332 and 336 exposed by the thirty-third and thirty-fifth holes 402 and 406, respectively, and the first and third sacrificial pillars 322 and 326 thereunder may be removed to form the twenty-third and twenty-fifth holes, respectively, again, and fourth to sixth sacrificial pillars 412, 414 and 416 may be formed in the twenty-third and twenty-fifth holes and the thirty-third to thirty-fifth holes 402, 404 and 406.

For example, the fourth sacrificial pillar 412 may be formed in the twenty-third hole and the thirty-third hole 402, the fifth sacrificial pillar 414 may be formed in the thirty-fourth hole 404, and the sixth sacrificial pillar 416 may be formed in the twenty-fifth hole and the thirty-fifth hole 406. In an example embodiment, each of the fourth to sixth sacrificial pillars 412, 414 and 416 may include an insulating material containing carbon, for example, silicon carbonitride (SiCN).

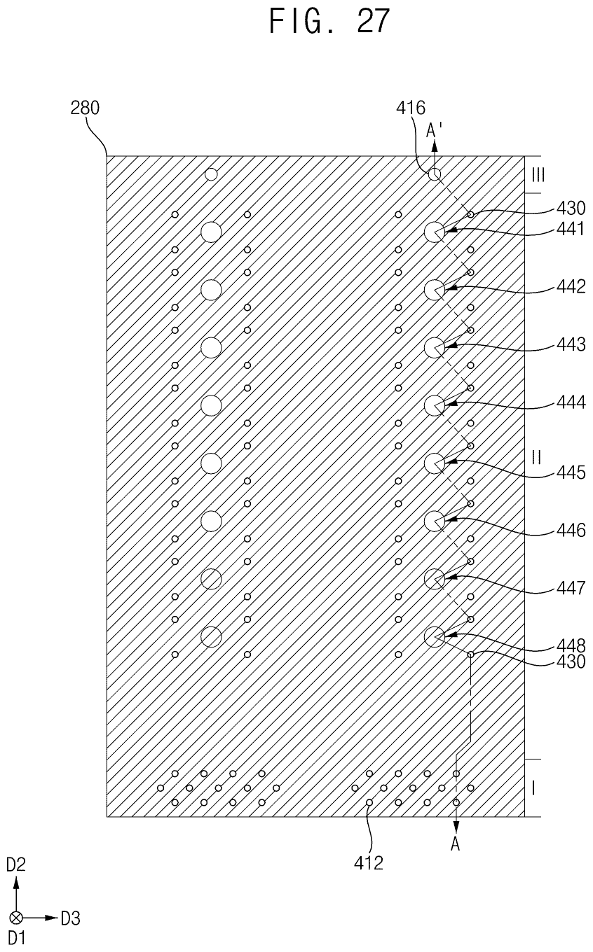

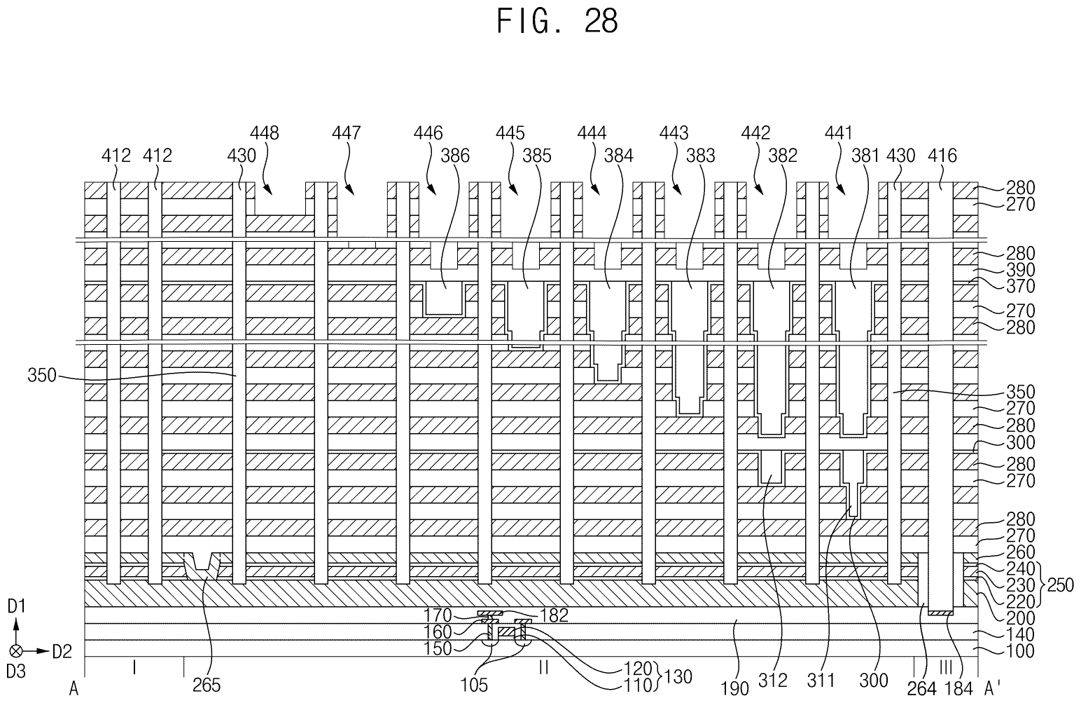

Referring to FIGS. 27 and 28, a second sacrificial insulating interlayer may be formed on an uppermost one of the fourth sacrificial layers 280 of the third mold layer and the fourth to sixth sacrificial pillars 412, 414 and 416, a thirty-sixth hole may be formed through the second sacrificial insulating interlayer to expose an upper surface of the fifth sacrificial pillar 414, and the fifth sacrificial pillar 414 may be removed to form the thirty-fourth hole 404 again.

A second support structure 430 may be formed in the thirty-fourth hole 404 and the thirty-sixth hole, and a planarization process may be performed until an upper surface of the uppermost one of the fourth sacrificial layers 280 of the third mold layer is exposed.

Thus, the second sacrificial insulating interlayer may be removed, and the second support structure 430 may remain in the thirty-fourth hole 404. The second support structure 430 may include oxide (e.g., silicon oxide), and in some example embodiments, the second support structure 430 may include substantially the same material as the first support structure 350 to be merged thereto.

Processes substantially the same as or similar to those illustrated with respect to FIGS. 1 to 8 may be performed to form thirty-seventh to forty-fourth holes 441, 442, 443, 444, 445, 446, 447 and 448 partially through the third mold layer on the second region II of the substrate 100.

In some example embodiments, the thirty-seventh to forty-fourth holes 441, 442, 443, 444, 445, 446, 447 and 448 may be formed to be spaced apart from each other in the second direction D2 on the second region II of the substrate 100. The thirty-seventh to forty-second holes 441, 442, 443, 444, 445 and 446 may expose an upper surface of the third insulating interlayer 390, and may overlap the seventh to twelfth sacrificial patterns 381, 382, 383, 384, 385 and 386, respectively, in the first direction D1.

The forty-third and forty-fourth holes 447 and 448 may expose upper surfaces of corresponding ones, respectively, of the fourth sacrificial layers 289 of the third mold layer. For example, the forty-fourth hole 448 may expose an upper surface of a lowermost one of the fourth sacrificial layers 280 in the third mold layer, and the forty-third hole 447 may expose an upper surface of one of the fourth sacrificial layers 280 at a second level from above in the third mold layer.

FIGS. 27 and 28 show eight holes (e.g., the thirty-seventh to forty-fourth holes 441, 442, 443, 444, 445, 446, 447 and 448) exposing upper surfaces of corresponding ones of the fourth sacrificial layers 280 included in the third mold layer. However, the inventive concepts may not be limited thereto, and in some example embodiments, more than eight holes may be formed.

In some example embodiments, each of the thirty-seventh to forty-fourth holes 441, 442, 443, 444, 445, 446, 447 and 448 may be formed between the second support structures 430 in a plan view. For example, the second support structures 430 may be formed at vertices of a rectangle, respectively, in a plan view, and each of the thirty-seventh to forty-fourth holes 441, 442, 443, 444, 445, 446, 447 and 448 may be formed in an inside of the rectangle in a plan view.

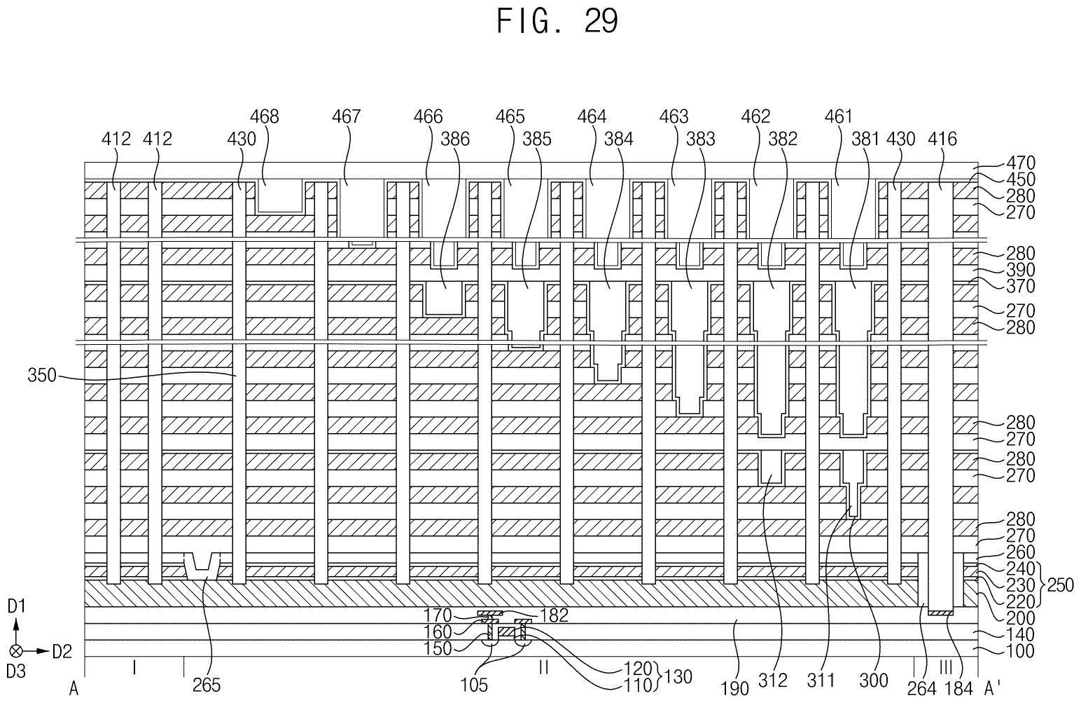

Referring to FIG. 29, a third spacer layer 450 may be formed on inner walls of the thirty-seventh to forty-fourth holes 441, 442, 443, 444, 445, 446, 447 and 448, the upper surface of the uppermost one of the fourth sacrificial layers 280 of the third mold layer, upper surfaces of the fourth and sixth sacrificial pillars 412 and 416 and an upper surface of the second support structure 430, a ninth sacrificial layer may be formed on the third spacer layer 450 to fill the thirty-seventh to forty-fourth holes 441, 442, 443, 444, 445, 446, 447 and 448, and a planarization process may be performed on the ninth sacrificial layer until an upper surface of a portion of the third spacer layer 450 on the uppermost one of the fourth sacrificial layers 280 is exposed to form thirteenth to twentieth sacrificial patterns 461, 462, 463, 464, 465, 466, 467 and 468 in the thirty-seventh to forty-fourth holes 441, 442, 443, 444, 445, 446, 447 and 448, respectively.

The third spacer layer 450 may include oxide (e.g., silicon oxide), and the ninth sacrificial layer may include, for example, polysilicon.

A fourth insulating interlayer 470 may be formed on the third spacer layer 450 and the thirteenth to twentieth sacrificial patterns 461, 462, 463, 464, 465, 466, 467 and 468. The fourth insulating interlayer 470 may include oxide (e.g., silicon oxide).

Referring to FIGS. 30 and 31, a forty-fifth hole may be formed through the fourth insulating interlayer 470 and the third spacer layer 450 to expose the fourth sacrificial pillar 412, the fourth sacrificial pillar 412 may be removed to form the thirty-third hole 402 and the twenty-third hole again, and a first memory channel structure 550 may be formed therein.

In some example embodiments, the first memory channel structure 550 may include a first filling pattern 530 extending in the first direction D1, a first channel 520 covering a sidewall and a lower surface of the first filling pattern 530, a first charge storage structure 510 covering a sidewall and a lower surface of the first channel 520, and a first capping pattern 540 on the first filling pattern 530, the first channel 520 and the first charge storage structure 510. The first charge storage structure 510 may include a first tunnel insulation pattern 500, a first charge storage pattern 490 and a first blocking pattern 480 sequentially stacked on a sidewall and a lower surface of the first channel 520.

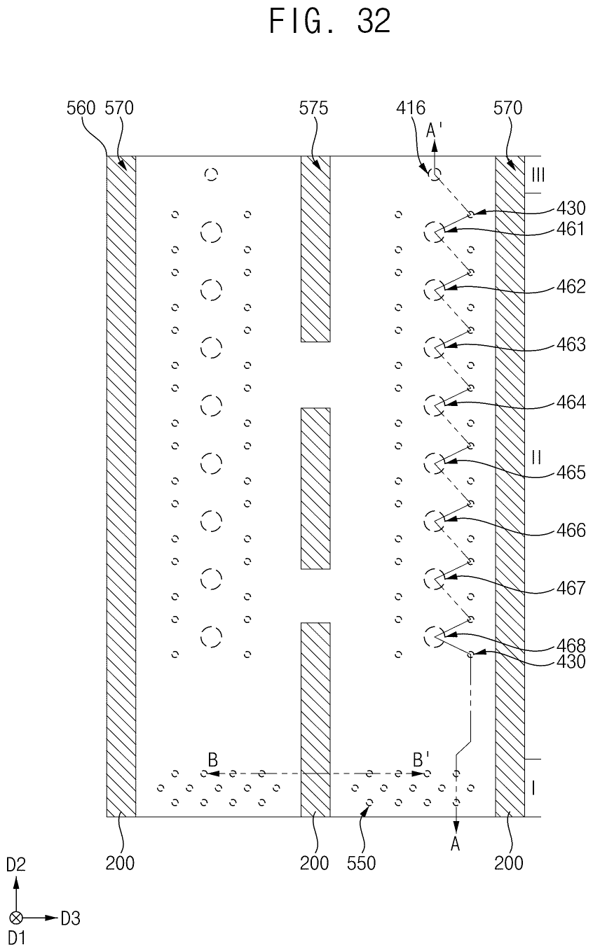

Referring to FIGS. 32 and 33, a fifth insulating interlayer 560 may be formed on the fourth insulating interlayer 470 and the first memory channel structure 550, and a second opening 570 may be formed by an etching process to extend in the second direction D2 through the third to fifth insulating interlayers 390, 470 and 560, the first to third mold layers, the support layer 260, the support pattern 265 and the sacrificial layer structure 250 on the first and second regions I and II of the substrate 100.

In some example embodiments, the second opening 570 may extend through the support pattern 265 to expose the upper surface of the CSP 200 on the second region II of the substrate 100, and may extend through the support layer 260 and the sacrificial layer structure 250 to expose the upper surface of the CSP 200 on the first region I of the substrate 100.

In some example embodiments, the second opening 570 may extend in the second direction D2 on the first and second regions I and II of the substrate 100 to opposite end portions in the second direction of the first to third mold layers, and a plurality of second openings 570 may be spaced apart from each other in the third direction D3. Thus, the first to third mold layers may be divided into first to third molds, respectively, by the second opening 570 on the first and second regions I and II of the substrate 100, and the second insulation layers 270 and the fourth sacrificial layers 280 in each of the first to third mold layers may be divided into second insulation patterns 275 and fourth sacrificial patterns 285, respectively, each of which may extend in the second direction D2.

However, the second opening 570 may not extend on the third region III of the substrate 100, and thus the first to third mold layers may not be divided into the first to third molds, respectively, on the third region III of the substrate 100. Accordingly, the first to third mold layers including the second insulation layers 270 and the fourth sacrificial layers 280 alternately and repeatedly stacked may remain on the third region III of the substrate 100.

In the etching process, a third opening 575 may also be formed through the third to fifth insulating interlayers 390, 470 and 560, the first to third mold layers, the support layer 260, the support pattern 265 and the sacrificial layer structure to expose the upper surface of the CSP 200 on the first and second regions I and II of the substrate 100. In some example embodiments, the third opening 575 may be formed between neighboring ones of the second openings 570 in the third direction D3 on the first and second regions I and II of the substrate 100, and a plurality of third openings 575 may be spaced apart from each other in the second direction D2.

When the first to third mold layers are divided into the first to third molds extending in the second direction D2 by the etching process, the first to third molds may not fall down by the first and second support structures 350 and 430 and the first memory channel structure 550.

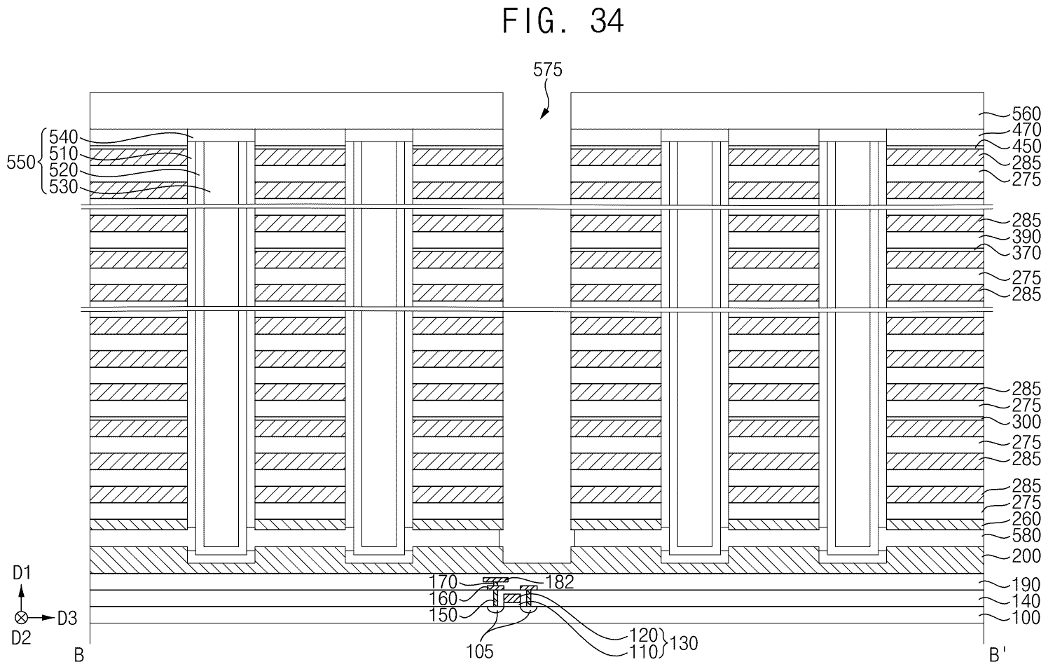

Referring to FIG. 34, a wet etching process may be performed through the second and third openings 570 and 575, and thus the sacrificial layer structure may be removed to form a first gap between the CSP 200 and the support layer 260 on the first region I of the substrate 100.

The wet etching process may be performed using an etching solution, for example, HF and/or H₃PO₄. In some example embodiments, the second and third openings 570 and 575 may extend through the support pattern 265 to expose the upper surface of the CSP 200 on the second region II of the substrate 100, instead of extending through the support layer 260 to expose the upper surface of the CSP 200, and thus, when the wet etching process is performed, the sacrificial layer structure 250 may not be removed by the support pattern 265. Additionally, the second and third openings 570 and 575 may not be formed on the third region III of the substrate 100, and thus the sacrificial layer structure on the third region III of the substrate 100 may not be removed.

As the first gap is formed, a portion of a sidewall of the first charge storage structure 510 may be exposed, and the portion of the sidewall of the first charge storage structure 510 may also be removed by the wet etching process to expose a portion of an outer sidewall of the first channel 520. Thus, the first charge storage structure 510 may be divided into an upper portion extending through the first to third mold layers to cover most portion of the outer sidewall of the first channel 520 and a lower portion covering a lower surface of the first channel 520 on the CSP 200.

A channel connection layer may be formed on sidewalls of the second and third openings 570 and 575 and in the first gap, and for example, an etch back process may be performed to remove a portion of the channel connection layer in the second and third openings 570 and 575 to form a channel connection pattern 580 in the first gap.

As the channel connection pattern 580 is formed, the first channels 520 between neighboring ones of the second openings 570 in the third direction D3 on the first region I of the substrate 100 may be electrically connected to each other.

An air gap may be formed in the channel connection pattern 580.

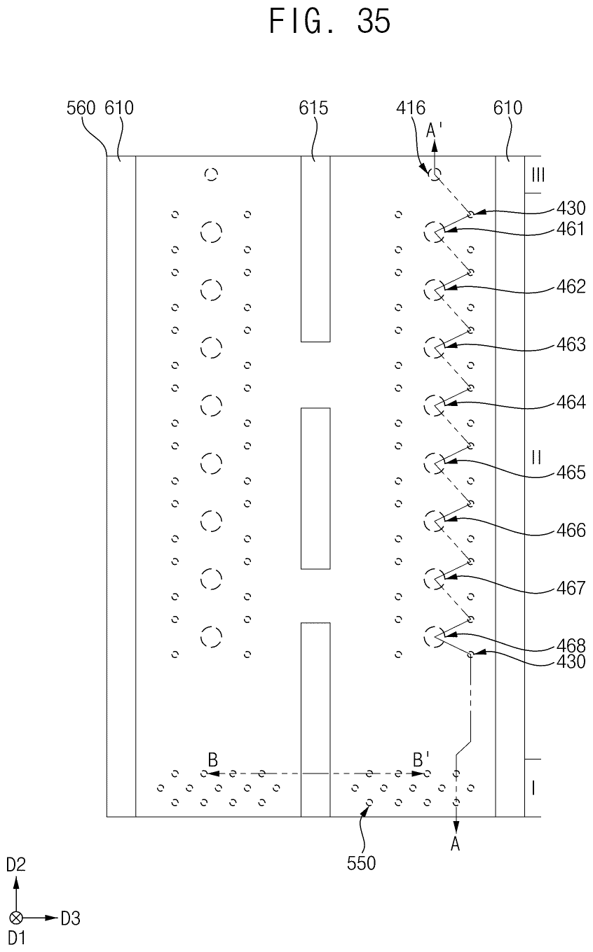

Referring to FIGS. 35 to 37, the fourth sacrificial patterns 285 exposed by the second and third openings 570 and 575 may be removed to form a second gap between neighboring ones of the second insulation patterns 275 in the first direction D1, and a portion of an outer sidewall of the first charge storage structure 510 included in the first memory channel structure 550, a portion of a sidewall of each of the first and second support structures 350 and 430, and a portion of a sidewall of each of the thirteenth to twentieth sacrificial patterns 461, 462, 463, 464, 465, 466, 467 and 468 may be exposed by the second gap.

In some example embodiments, the fourth sacrificial patterns 285 may be removed by a wet etching process using an etching solution including, for example, H₃PO₄ or H₂SO₄.

The wet etching process may be performed through the second and third openings 570 and 575, and a portion of the fourth sacrificial pattern 285 between neighboring ones of the second and third openings 570 and 575 may be entirely removed by the etching solution that may inflow from the second and third openings 570 and 575 in both opposite directions on the first and second regions I and II of the substrate 100.

A second blocking layer may be formed on the portion of the outer sidewall of the first charge storage structure 510, the portion of the sidewall of each of the first and second support structures 350 and 430, and the portion of the sidewall of each of the thirteenth to twentieth sacrificial patterns 461, 462, 463, 464, 465, 466, 467 and 468, an inner wall of each of the second gaps, surfaces of the second insulation patterns 275, sidewalls of the first to third spacer layers 300, 370 and 450, the third to fifth insulating interlayers 390, 470 and 560 and an upper surface of the fifth insulating interlayer 560, and a first gate electrode layer may be formed on the second blocking layer.

The first gate electrode layer may be partially removed to form a first gate electrode 600 in each of the second gaps. In some example embodiments, the first gate electrode layer may be partially removed by a wet etching process.

In some example embodiments, the first gate electrode 600 may extend in the second direction D2, and a plurality of first gate electrodes 600 may be stacked in a plurality of levels, respectively, spaced apart from each other in the first direction D1 to form a preliminary gate electrode structure. In some example embodiments, a plurality of preliminary gate electrode structures may be spaced apart from each other in the third direction D3 by the second openings 570.

As illustrated above, a plurality of third openings 575 may be spaced apart from each other in the second direction D2 on the first and second regions I and II of the substrate 100, and thus the preliminary gate electrode structure may not be divided in the third direction D3 by the third openings 575.

The second and third openings 570 and 575 may be formed only on the first and second regions I and II of the substrate 100, and thus the fourth sacrificial layers 280 on the third region III of the substrate 100 may not be removed but remain.

A first division layer may be formed on the second blocking layer to fill the second and third openings 570 and 575, and a planarization process may be performed on the first division layer and the second blocking layer until an upper surface of the fifth insulating interlayer 560 is exposed.

Thus, the second blocking layer may be transformed into a second blocking pattern 590, and first and second division patterns 610 and 615 may be formed in the second and third openings 570 and 575, respectively.

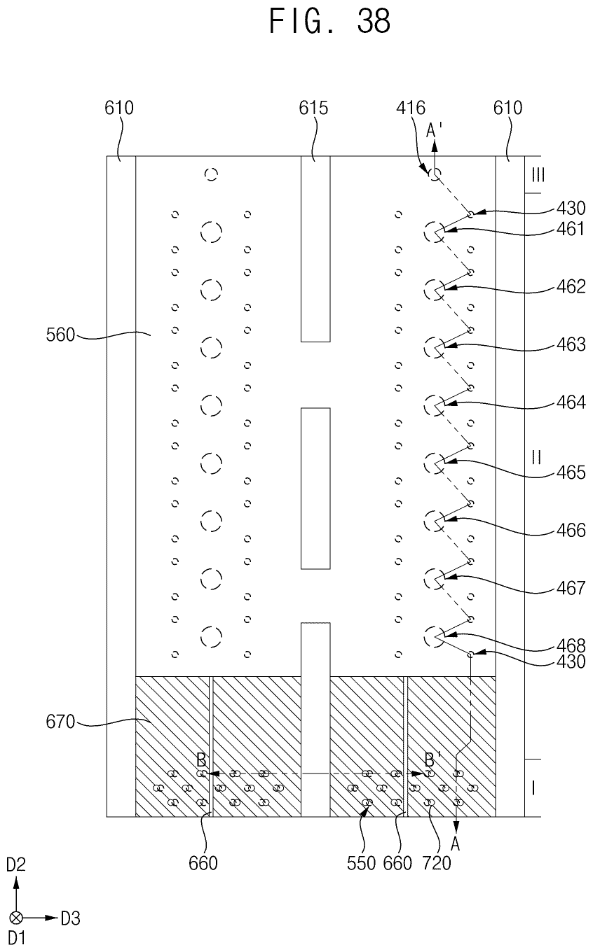

Referring to FIGS. 38 to 40, a portion of the fifth insulating interlayer 560 on the first region I and a portion of the second region II adjacent to the first region I of the substrate 100 may be removed to form a fourth opening exposing an upper surface of the fourth insulating interlayer 470, and a sixth insulating interlayer 630, the etch stop layer 640 and the second gate electrode layer may be sequentially stacked on the upper surface of the fourth insulating interlayer 470 to fill the fourth opening.

The sixth insulating interlayer 630 may include insulating nitride (e.g., silicon nitride), the etch stop layer 640 may include oxide (e.g., silicon oxide), and the second gate electrode layer may include, for example, doped polysilicon.

A fifth opening may be formed through the second gate electrode layer and the etch stop layer 640 to expose an upper surface of the sixth insulating interlayer 630, and a third division pattern 660 may be formed in the fifth opening. In some example embodiments, the third division pattern 660 may extend in the second direction D2 on the first region I and the portion of the second region II adjacent to the first region I of the substrate 100, and a plurality of third division patterns 660 may be spaced apart from each other in the third direction D3. Each of the third division patterns 660 may be formed between neighboring ones of the first and second division patterns 610 and 615.

As the third division pattern 660 is formed, the second gate electrode layer may be divided into second gate electrodes 650 each of which may extend in the second direction D2. The second gate electrode 650 and the preliminary gate electrode structure including the first gate electrode 600 may collectively form a gate electrode structure.

A forty-sixth hole may be formed through the second gate electrode 650 to expose an upper surface of the etch stop layer 640. In some example embodiments, a plurality of forty-sixth holes may be spaced apart from each other in the second and third directions D2 and D3 to partially overlap the first memory channel structure 550 in the first direction D1.

A second charge storage structure layer may be formed on a sidewall and a bottom of the forty-sixth hole, the first to third division patterns 610, 615 and 660 and the fifth insulating interlayer 560, and an etch back process may be performed on the second charge storage structure layer to form a second charge storage structure 680 on the sidewall and an edge portion of the bottom of the forty-sixth hole. The second charge storage structure 680 may include a third blocking pattern, a second charge storage pattern and a second tunnel insulation pattern sequentially sacked on the sidewall of the forty-sixth hole.

A portion of the etch stop layer 640 exposed by the forty-sixth hole and a portion of the sixth insulating interlayer 630 thereunder may be removed to enlarge the forty-sixth hole in the first direction D1, a portion of the sixth insulating interlayer 630 adjacent to the enlarged forty-sixth hole may be additionally removed to enlarge the forty-sixth hole in the horizontal direction, and thus, a forty-seventh hole may be formed to at least partially expose an upper surface of the first memory channel structure 550.

The forty-seventh hole may also expose an upper surface of a portion of the fourth insulating interlayer 470 adjacent to the first memory channel structure 550.

A second channel 690, a second filling pattern 700 and a second capping pattern 710 may be formed in the forty-seventh hole.

In some example embodiments, the second channel 690 may include a lower portion surrounded by the sixth insulating interlayer 630, a central portion surrounded by the etch stop layer 640, and an upper portion surrounded by the second charge storage structure 680. A lower surface and a sidewall of the second filling pattern 700 may be covered by the upper portion of the second channel 690. The second capping pattern 710 may be formed on the second channel 690 and the second filling pattern 700, and may be surrounded by the second charge storage structure 680.

The second charge storage structure 680, the second channel 690, the second filling pattern 700 and the second capping pattern 710 may collectively form a second memory channel structure 720, and the second memory channel structure 720 may contact the upper surface of the first memory channel structure 550 to be connected to the first memory channel structure 550.

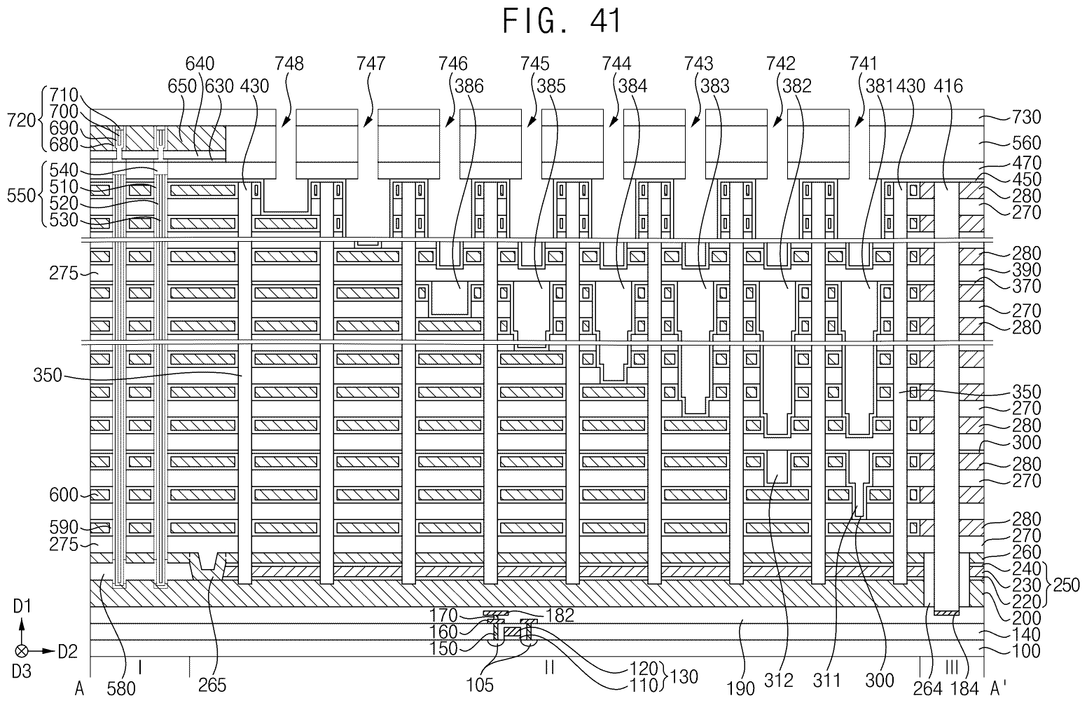

Referring to FIG. 41, a seventh insulating interlayer 730 may be formed on the second gate electrode 650, the second memory channel structure 720, the first to third division patterns 610, 615 and 660 and the fifth insulating interlayer 560. Forty-eighth to fifty-fifth holes 741, 742, 743, 744, 745, 746, 747 and 748 may be formed through the fourth, fifth and seventh insulating interlayers 470, 560 and 730 to expose upper surfaces of the thirteenth to twentieth sacrificial patterns 461, 462, 463, 464, 465, 466, 467 and 468, respectively. The thirteenth to twentieth sacrificial patterns 461, 462, 463, 464, 465, 466, 467 and 468 may be removed to enlarge the forty-eighth to fifty-fifth holes 741, 742, 743, 744, 745, 746, 747 and 748 in the first direction D1.

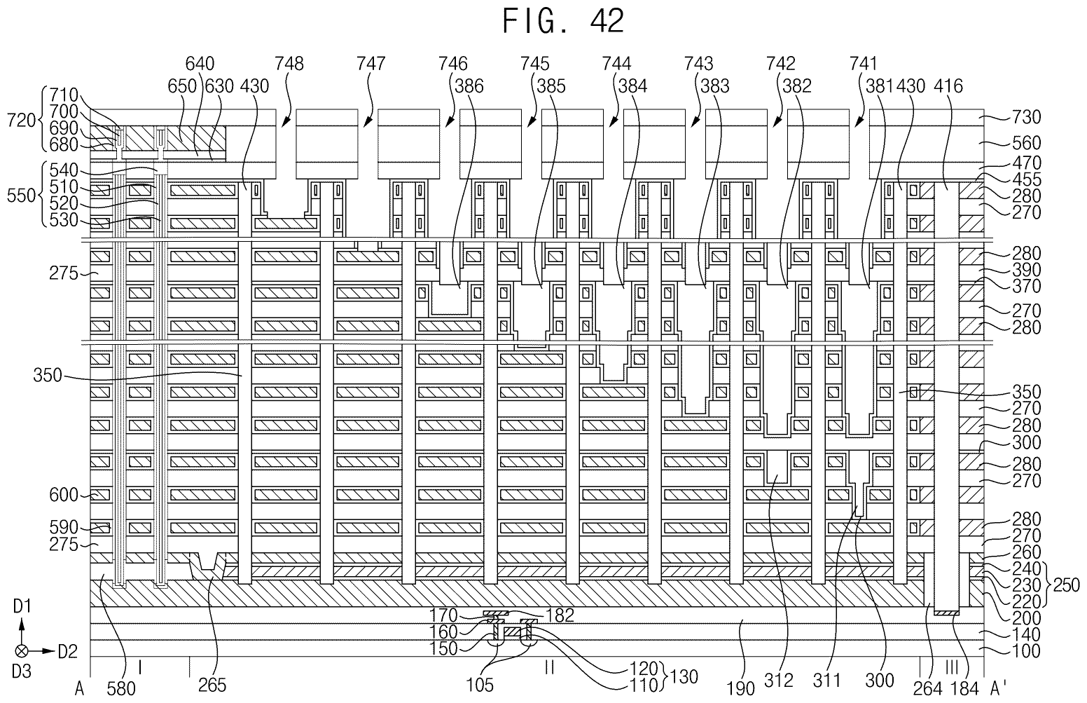

Referring to FIG. 42, an anisotropic etching process may be performed on the third spacer layer 450 to form a third spacer 455, and a portion of the second blocking pattern 590 exposed by the third spacer 455 and a portion of the third insulating interlayer 390 thereunder may be removed so that upper surfaces of the first gate electrode 600 and the seventh to twelfth sacrificial patterns 381, 382, 383, 384, 385 and 386 may be exposed.

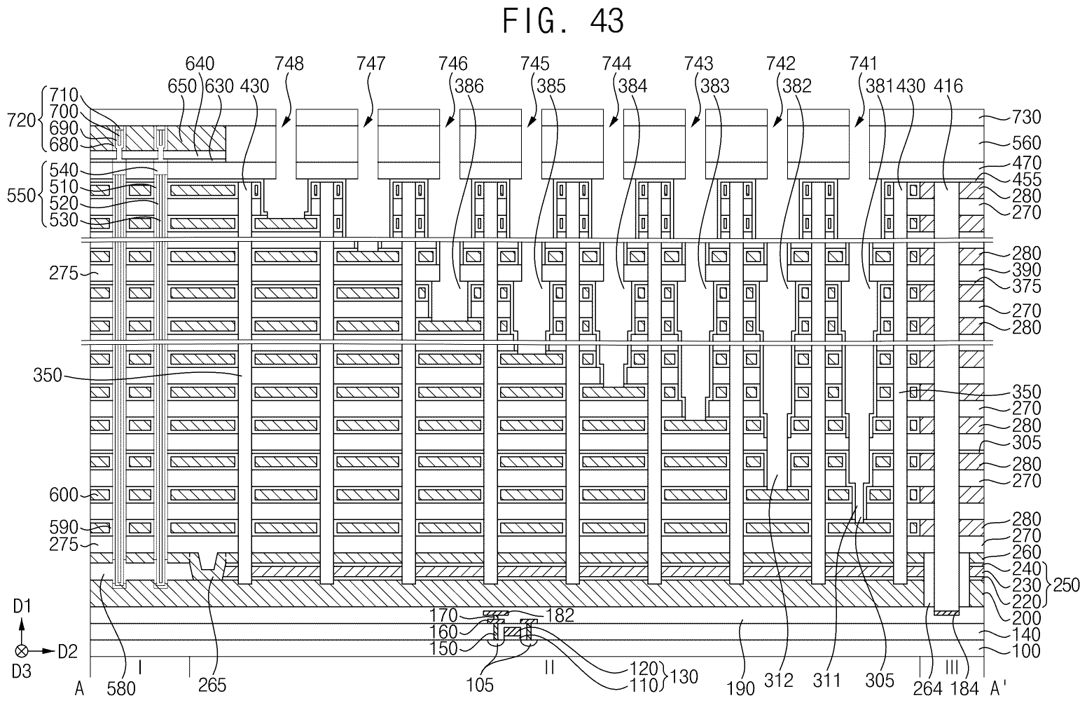

Referring to FIG. 43, the seventh to twelfth sacrificial patterns 381, 382, 383, 384, 385 and 386 may be removed to enlarge the forty-eighth to fifty-fifth holes 741, 742, 743, 744, 745, 746, 747 and 748 in the first direction D1, and thus the second spacer layer 370 may be partially exposed.

An anisotropic etching process may be performed on the exposed second spacer layer 370 to form a second spacer 375, and a portion of the second blocking pattern 590 exposed by the second spacer 375 and a portion of the second insulation pattern 275 thereunder may be removed so that upper surfaces of the first gate electrode 600 and the fifth and sixth sacrificial patterns 311 and 312 may be exposed.

The fifth and sixth sacrificial patterns 311 and 312 may be removed to enlarge the forty-eighth and forty-ninth holes 741 and 742 in the first direction D1, and thus the first spacer layer 300 may be partially exposed.

An anisotropic etching process may be performed on the exposed first spacer layer 300 to form a first spacer 305, and a portion of the second blocking pattern 590 exposed by the first spacer 305 may be removed so that an upper surface of the first gate electrode 600 may be exposed.

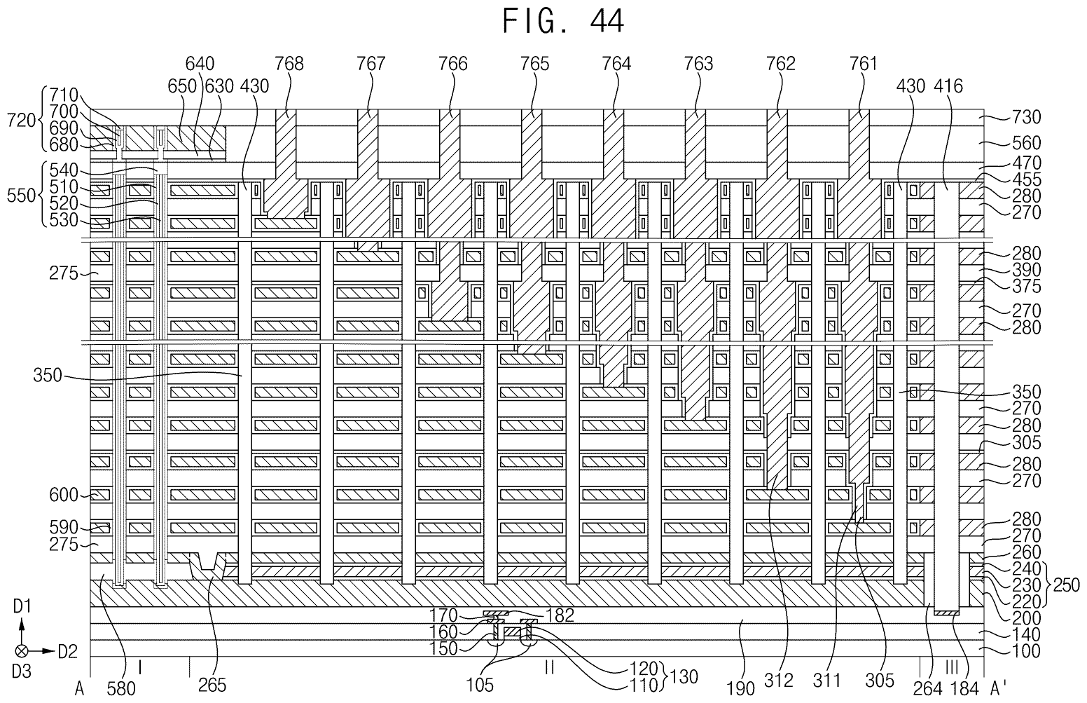

Referring to FIG. 44, first to eighth upper contact plugs 761, 762, 763, 764, 765, 766, 767 and 768 may be formed in the forty-eighth to fifty-fifth holes 741, 742, 743, 744, 745, 746, 747 and 748, respectively.

A ninth upper contact plug 769 may be formed through the seventh insulating interlayer 730 to contact an upper surface of the second gate electrode 650. In an example embodiment, the ninth upper contact plug 769 may be formed on a portion of the second region II adjacent to the first region I of the substrate 100.

In some example embodiments, each of the first to ninth upper contact plugs 761, 762, 763, 764, 765, 766, 767 and 768 may include a conductive pattern and a barrier pattern covering a sidewall and a lower surface of the conductive pattern.

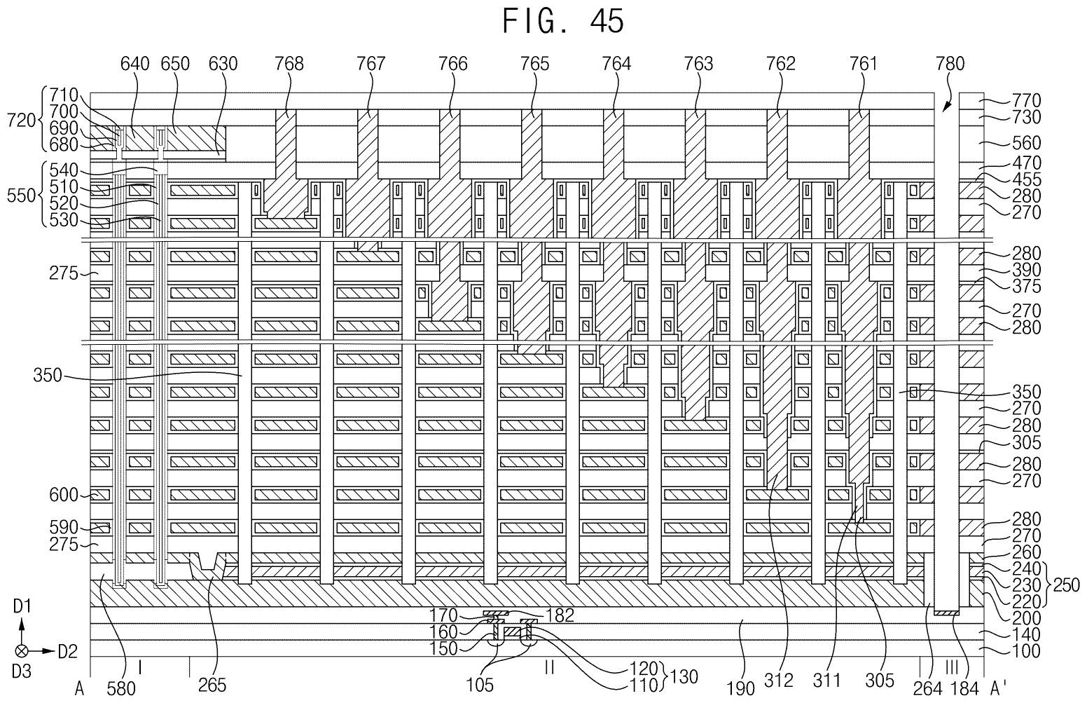

Referring to FIG. 45, an eighth insulating interlayer 770 may be formed on the seventh insulating interlayer 730 and the first to ninth upper contact plugs 761, 762, 763, 764, 765, 766, 767 and 768. A fifty-sixth hole 780 may be formed through the fourth, fifth, seventh and eighth insulating interlayers 470, 560, 730 and 770 and the third spacer 455 to expose an upper surface of the sixth sacrificial pillar 416. The exposed sixth sacrificial pillar 416 may be removed so that the fifty-sixth hole 780 is enlarged in the first direction D1 to expose an upper surface of the third lower wiring 184.

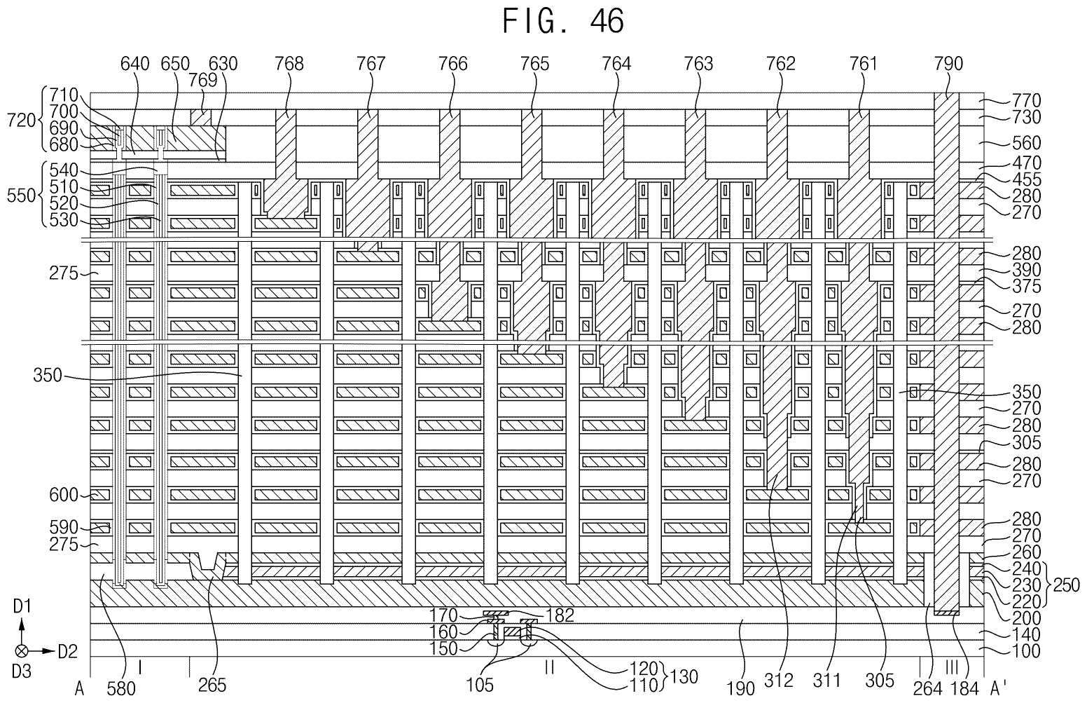

Referring to FIG. 46, a through via 790 may be formed in the enlarged fifty-sixth hole 780.

In some example embodiments, the through via 790 may include a conductive pattern and a barrier pattern covering a sidewall and a lower surface of the conductive pattern.

Referring to FIGS. 9 to 12 again, after forming a ninth insulating interlayer 800 on the eighth insulating interlayer 770 and the through via 790, a first upper via 810 extending through the seventh to ninth insulating interlayers 730, 770 and 800 to contact an upper surface of the second memory channel structure 720, a second upper via 820 extending through the eighth and ninth insulating interlayers 770 and 800 to contact an upper surface of each of the first to eighth upper contact plugs 761, 762, 763, 764, 765, 766, 767 and 768, a third upper via 825 extending through the eighth and ninth insulating interlayers 770 and 800 to contact an upper surface of the ninth upper contact plug 769, and a fourth upper via 830 extending through the ninth insulating interlayer 800 to contact an upper surface of the through via 790 may be formed.

A tenth insulating interlayer 840 may be formed on the ninth insulating interlayer 800 and the first to fourth upper vias 810, 820, 825 and 830, and first to fourth upper wirings 850, 860, 865 and 870 may be formed through the tenth insulating interlayer 840 to contact upper surfaces of the first to fourth upper vias 810, 820, 825 and 830, respectively, to complete the fabrication of the semiconductor device.

As illustrated above, the forty-eighth to fifty-fifth holes 741, 742, 743, 744, 745, 746, 747 and 748 may be formed partially through the gate electrode structure to expose the upper surface of a corresponding one of the first gate electrodes 600 by using the method of forming the hole illustrated with reference to FIGS. 1 to 8, and the first to third spacers 305, 375 and 455 may be formed on sidewalls thereof.

Thus, the first to eighth upper contact plugs 761, 762, 763, 764, 765, 766, 767 and 768 in the forty-eighth to fifty-fifth holes 741, 742, 743, 744, 745, 746, 747 and 748, respectively, may be electrically connected to only corresponding ones of the first gate electrodes 600, respectively, and may be electrically insulated from ones of the first gate electrodes 600 thereabove.

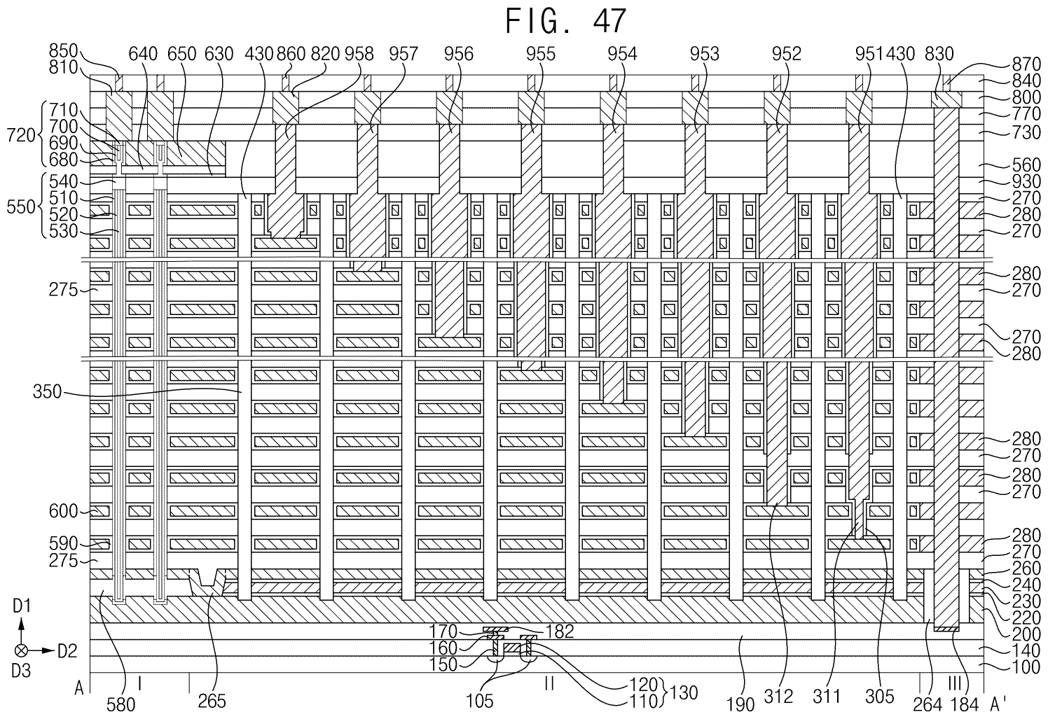

FIG. 47 is a cross-sectional view illustrating a semiconductor device in accordance with an example embodiment, which may correspond to FIG. 3. This semiconductor device may be substantially the same as or similar to that of FIGS. 9 to 12, and thus repeated explanations are omitted herein.

Referring to FIG. 47, the semiconductor device may not include the second spacer 375 and the third insulating interlayer 390, and thus the second and third mold layers may not be differentiated from each other.

Thus, the lower portion of each of the first to sixth upper contact plugs 761, 762, 763, 764, 765 and 766 may not be divided into the first and second lower portions with the third insulating interlayer 390 as a reference. Thus, the width of the lower portion of each of the first to sixth upper contact plugs 761, 762, 763, 764, 765 and 766 may decrease from a top toward a bottom thereof in the first direction D1.

The third spacer 455 may cover the sidewall of the lower portion of each of the first to eighth upper contact plugs 761, 762, 763, 764, 765, 766, 767 and 768, but may not be disposed on the uppermost one of the fourth sacrificial layers 280 included in the third mold layer and the second blocking pattern 590 contacting the uppermost one of the fourth sacrificial layers 280.

The first support structure 350 shown in FIGS. 9 to 12 may be merged to the second support structure 430.

An eleventh insulating interlayer 930 may be formed instead of the fourth insulating interlayer 470.

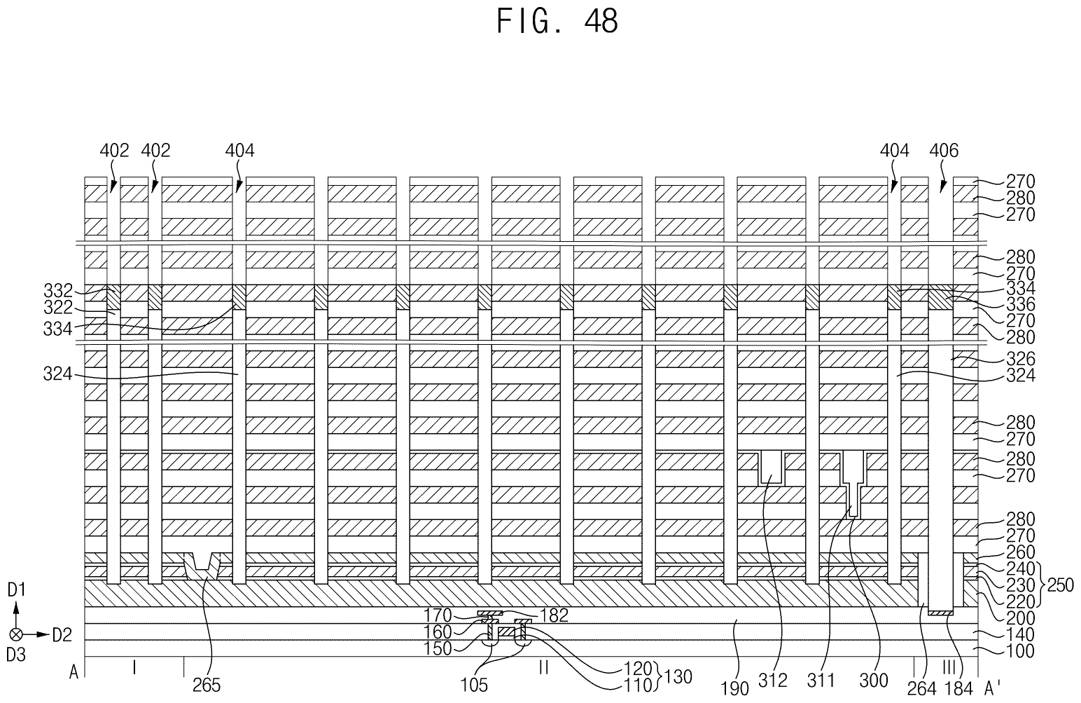

FIGS. 48 to 55 are cross-sectional views taken along lines A-A′ (see FIG. 10) to illustrate a method of manufacturing the semiconductor device of FIG. 47. This method may include processes substantially the same as or similar to those illustrated with respect to FIGS. 13 to 46 and FIGS. 9 to 12, and thus repeated explanations thereof are omitted herein.

Referring to FIG. 48, processes substantially the same as or similar to those illustrated with respect to FIGS. 9 to 20 may be performed, and with performing the processes illustrated with reference to FIGS. 21 to 24, processes substantially the same as or similar to those illustrated with respect to FIG. 25 may be performed so that the third mold layer may be formed on the second mold layer and the first and third sacrificial patterns 332 and 336.

The thirty-third to thirty-fifth holes 402, 404 and 406 may be formed through the third mold layer to expose upper surfaces of the first to third sacrificial capping patterns 332, 334 and 336, respectively.

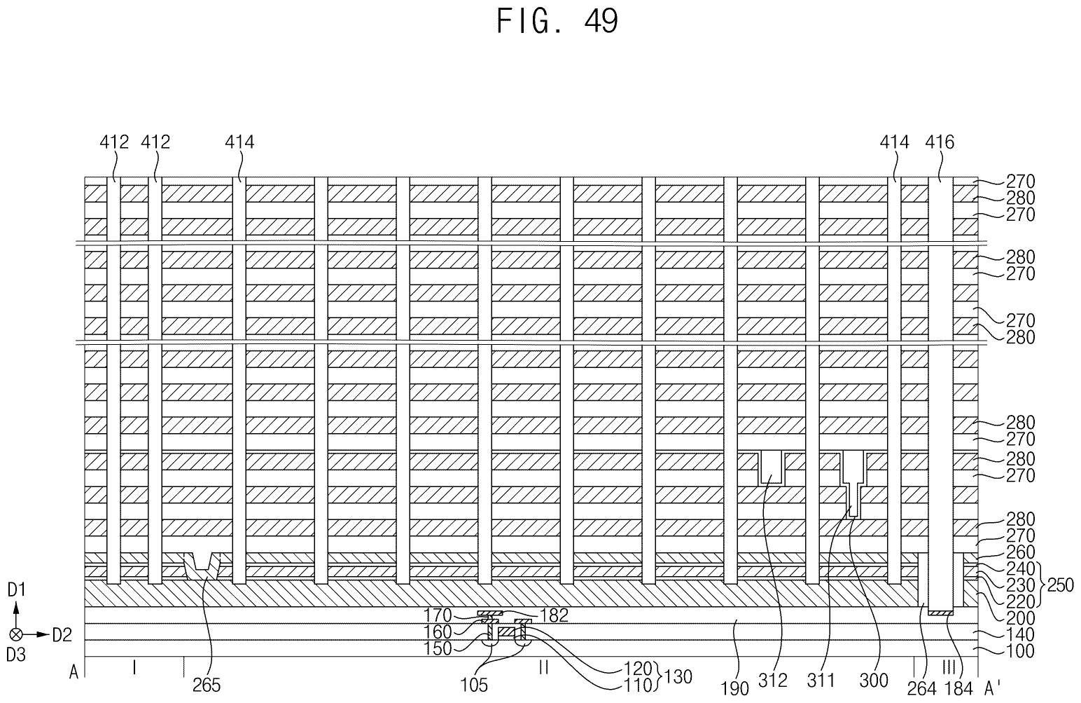

Referring to FIG. 49, the first to third sacrificial patterns 332, 334 and 336 may be removed exposed by the thirty-third to thirty-fifth holes 402, 404 and 406 may be removed to enlarge the thirty-third to thirty-fifth holes 402, 404 and 406 in the first direction D1, and the fourth to sixth sacrificial pillars 412, 414 and 416 may be formed in the enlarged thirty-third and thirty-fifth holes 402, 404 and 406, respectively.

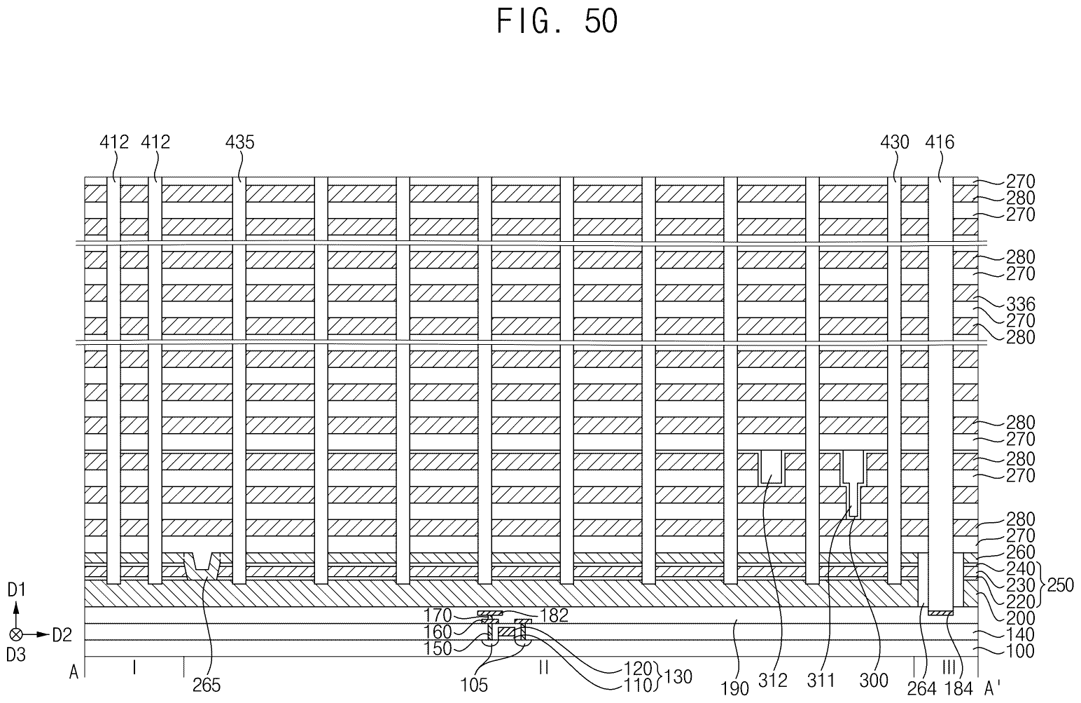

Referring to FIG. 50, the fifth sacrificial pillar 414 may be removed to form a fifty-seventh hole, and a third support structure 435 may be formed in the fifty-seventh hole.

The third support structure 435 may include oxide (e.g., silicon oxide).

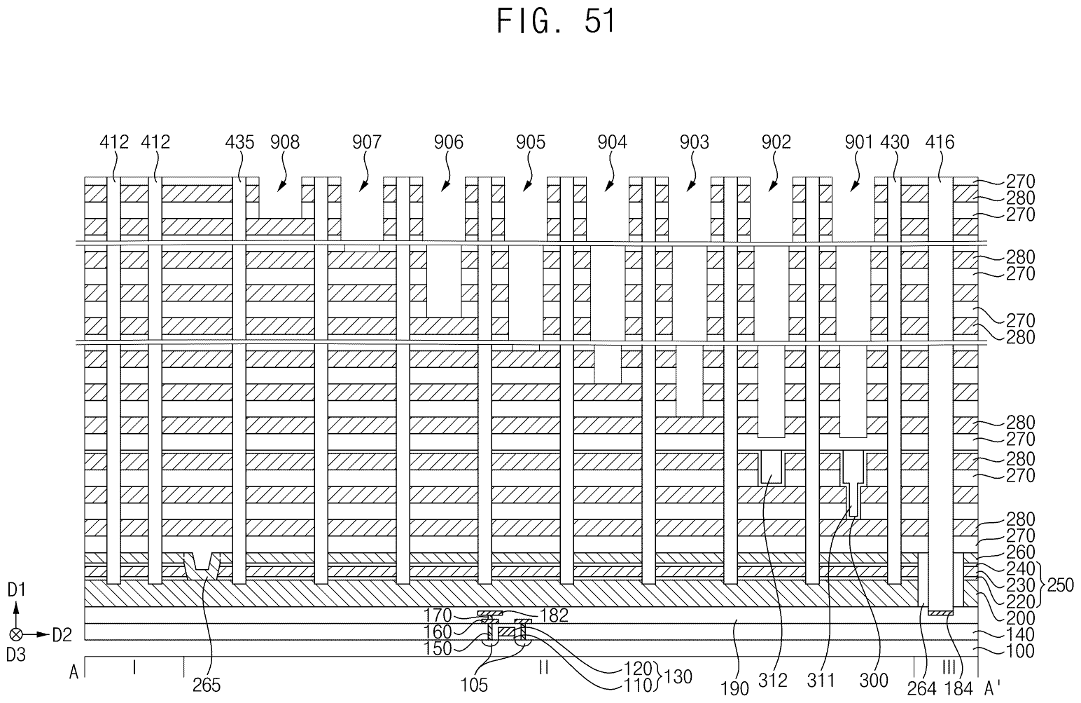

Referring to FIG. 51, processes substantially the same as or similar to those illustrated with respect to FIGS. 1 to 8 may be performed so that fifty-eighth to sixty-fifth holes 901, 902, 903, 904, 905, 906, 907 and 908 may be formed partially through the second and third mold layers on the second region II of the substrate 100.

In some example embodiments, the fifty-eighth to sixty-fifth holes 901, 902, 903, 904, 905, 906, 907 and 908 may be formed to be spaced apart from each other in the second direction D2 on the second region II of the substrate 100. The fifty-eighth and fifth-ninth holes 901 and 902 may expose an upper surface of a lowermost one of the second insulation layers 270 of the second mold layer, and may overlap the fifth and sixth sacrificial patterns 311 and 312, respectively, in the first direction D1.

The sixty to sixty-fifth holes 903, 904, 905, 906, 907 and 908 may expose upper surfaces of corresponding ones of the fourth sacrificial layers 280 of the second mold layer or the third mold layer, respectively. For example, the sixty hole 903 may expose an upper surface of a lowermost one of the fourth sacrificial layers 280 included in the second mold layer, and the sixty-fifth hole 908 may expose an upper surface of one of the fourth sacrificial layers 280 at a second level from above included in the third mold layer.

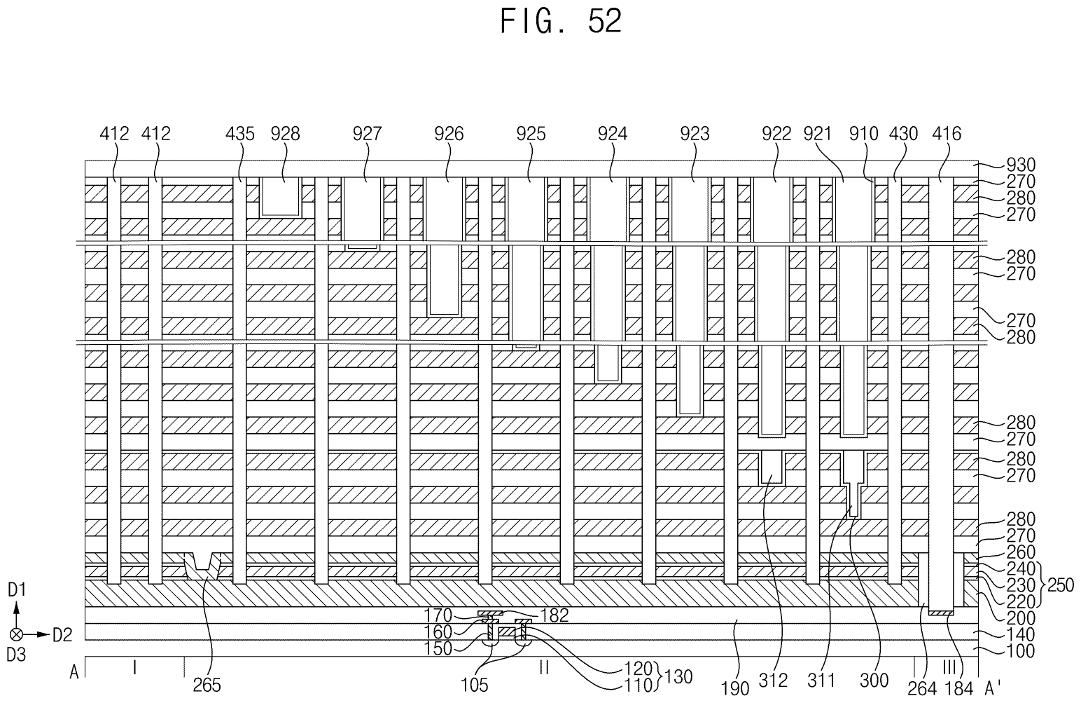

Referring to FIG. 52, a fourth spacer layer 910 may be formed on inner walls of the fifty-eighth to sixty-fifth holes 901, 902, 903, 904, 905, 906, 907 and 908. An uppermost one of the second insulation layers 270 included in the third mold layer, the fourth and sixth sacrificial pillars 412 and 416 and the third support structure 435, and twenty-first to twenty-eighth sacrificial patterns 921, 922, 923, 924, 925, 926, 927 and 928 may be formed in the fifty-eighth to sixty-fifth holes 901, 902, 903, 904, 905, 906, 907 and 908, respectively.

An eleventh insulating interlayer 930 may be formed on the twenty-first to twenty-eighth sacrificial patterns 921, 922, 923, 924, 925, 926, 927 and 928, the uppermost one of the second insulation layers 270 included in the third mold layer, the fourth and sixth sacrificial pillars 412 and 416 and the third support structure 435.

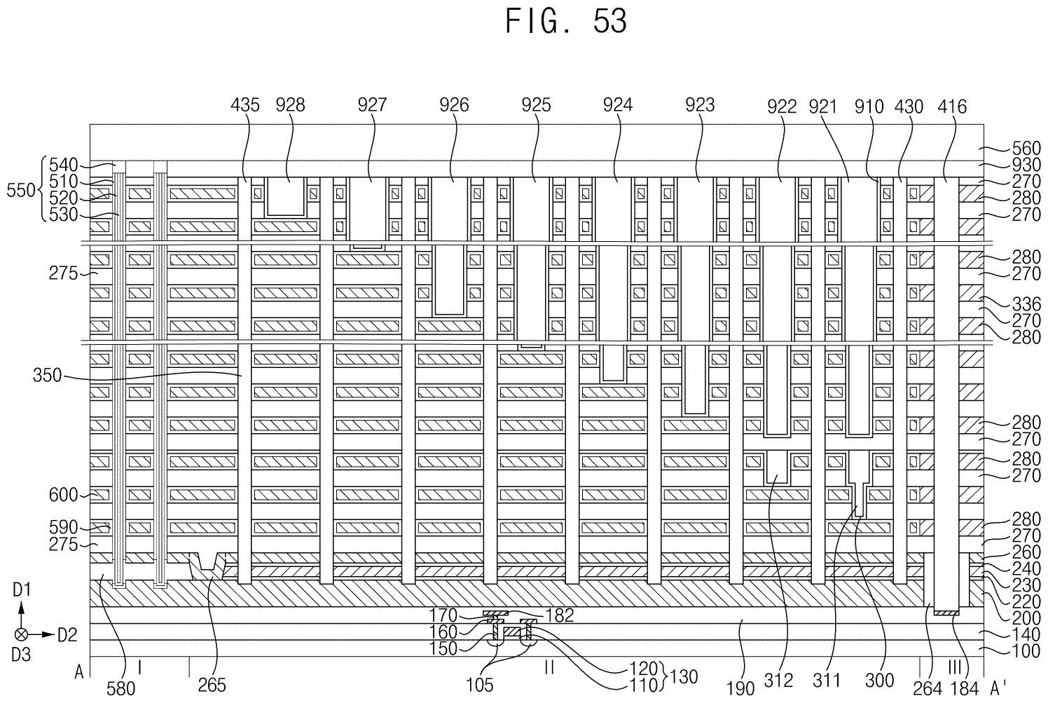

Referring to FIG. 53, processes substantially the same as or similar to those illustrated with respect to FIGS. 30 to 37 may be performed to form the first memory channel structure 550, the fifth insulating interlayer 560, the channel connection pattern 580, the second blocking pattern 590, the first gate electrode 600 and the first and second division patterns 610 and 615.

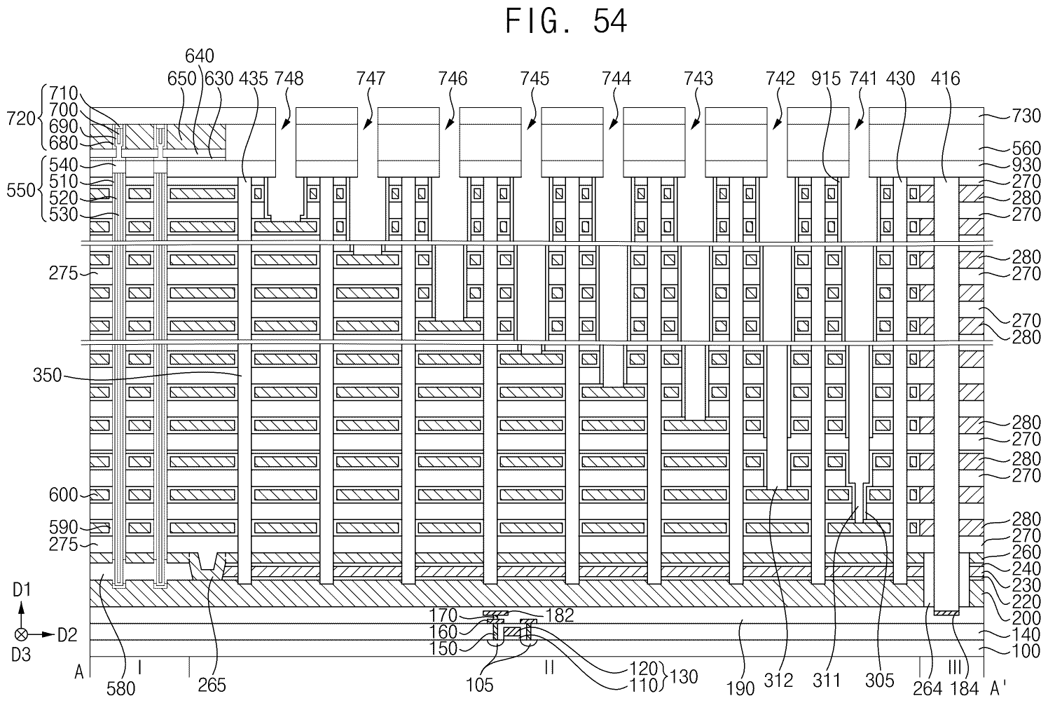

Referring to FIG. 54, processes substantially the same as or similar to those illustrated with respect to FIGS. 38 to 43 may be performed to form the second gate electrode 650, the second memory channel structure 720, the third division pattern 660 and the seventh insulating interlayer 730, etc.

Additionally, the forty-eighth to fifty-fifth holes 741, 742, 743, 744, 745, 746, 747 and 748 and the first and fourth spacers 305 and 915 may be formed.

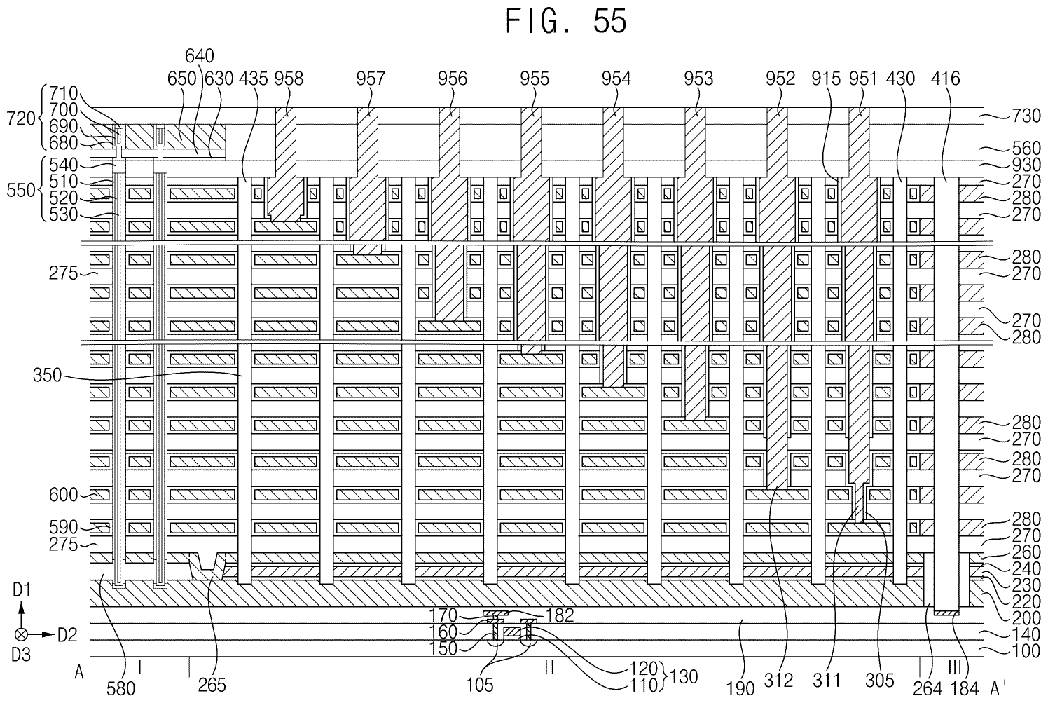

Referring to FIG. 55, tenth to seventeenth upper contact plugs 951, 952, 953, 954, 955, 956, 957 and 958 may be formed in the forty-eighth to fifty-fifth holes 741, 742, 743, 744, 745, 746, 747 and 748, respectively.

Referring to FIG. 47 again, processes substantially the same as or similar to those illustrated with respect to FIG. 46 and FIGS. 9 to 12 may be performed to complete the fabrication of the semiconductor device.

While some example embodiments have been particularly shown and described, it will be understood by one of ordinary skill in the art that variations in form and detail may be made therein without departing from the spirit and scope of the claims.

What is claimed is:

1. A semiconductor device comprising:
a gate electrode structure on a substrate, the gate electrode structure including gate electrodes sequentially stacked and spaced apart from each other in a first direction, the first direction being substantially perpendicular to an upper surface of the substrate, and each of the gate electrodes extending in a second direction, the second direction being substantially parallel to the upper surface of the substrate;
a memory channel structure extending through the gate electrode structure; and
a contact plug extending partially through the gate electrode structure to contact an upper surface of a first gate electrode among the gate electrodes, the contact plug extending through but being electrically insulated from a second gate electrode that is over the first gate electrode, and at least a portion of the contact plug having a width decreasing from a top toward a bottom thereof in the first direction in a stepwise manner.

2. The semiconductor device according to claim 1, further comprising:
a spacer on a sidewall of the contact plug, the spacer electrically insulating the second gate electrode from the contact plug.

3. The semiconductor device according to claim 2, wherein
the contact plug includes a lower portion and an upper portion stacked in the first direction, and
the spacer is on a sidewall of the lower portion of the contact plug.

4. The semiconductor device according to claim 3, wherein a width of an upper surface of the lower portion of the contact plug is greater than a width of a lower surface of the upper portion of the contact plug.

5. The semiconductor device according to claim 4, wherein
the lower portion of the contact plug includes a first lower portion and a second lower portion stacked in the first direction, and
each of the first and second lower portions of the contact plug has a width decreasing from a top toward a bottom thereof in the first direction in a stepwise manner.

6. The semiconductor device according to claim 1, further comprising:
a blocking pattern including metal oxide, the blocking pattern covering lower and upper surfaces of each of the gate electrodes, a sidewall of each of the gate electrodes facing the memory channel structure and a sidewall of each of the gate electrodes facing the contact plug.

7. The semiconductor device according to claim 6, further comprising:
a spacer on a sidewall of the contact plug,
wherein the spacer contacts a sidewall of the blocking pattern.

8. The semiconductor device according to claim 1, further comprising:
a plurality of contact plugs, the contact plug being one of the plurality of contact plugs,
wherein heights of lower surfaces of the contact plugs decrease in the second direction.

9. The semiconductor device according to claim 8, further comprising:
support structures extending through the gate electrode structure,
wherein each of the plurality of contact plugs is in an inside of an area defined by the support structures in a plan view.

10. The semiconductor device according to claim 1, wherein the gate electrodes have substantially a same length in the second direction.

11. A semiconductor device comprising:
A gate electrode structure on a substrate, the gate electrode structure including gate electrodes sequentially stacked and spaced apart from each other in a first direction, the first direction being substantially perpendicular to an upper surface of the substrate, and each of the gate electrodes extending in a second direction, the second direction being substantially parallel to the upper surface of the substrate;
a memory channel structure extending through the gate electrode structure;
an insulating interlayer on the gate electrode structure and the memory channel structure; and
a contact plug extending through the insulating interlayer and a portion of the gate electrode structure to contact an upper surface of a first one of the gate electrodes, the contact plug extending through but being electrically insulated from a second one of the gate electrodes that is over the first one of the gate electrodes,
wherein the contact plug includes
first and second lower portions stacked in the first direction and extending through the portion of the gate electrode structure, and
an upper portion on the second lower portion and extending through the insulating interlayer, and
wherein each of the first and second lower portions has a width decreasing from a top toward a bottom thereon in the first direction in a stepwise manner.

12. The semiconductor device according to claim 11, wherein a width of an upper surface of the lower portion of the contact plug is greater than a width of a lower surface of the upper portion of the contact plug.

13. The semiconductor device according to claim 11, further comprising:
a spacer on sidewalls of the first and second lower portions of the contact plug, the spacer including an insulating material.

14. The semiconductor device according to claim 13, wherein
the spacer includes a first spacer portion and a second spacer portion on the sidewalls of the first lower portion and the second lower portion of the contact plug, respectively, and
wherein the first spacer portion and the second spacer portion are not in contact with each other.

15. The semiconductor device according to claim 11, further comprising:
a blocking pattern including metal oxide, the blocking pattern covering lower and upper surfaces of each of the gate electrodes, a sidewall of each of the gate electrodes facing the memory channel structure and a sidewall of each of the gate electrodes facing the contact plug.

16. A semiconductor device comprising:
a gate electrode structure including
first gate electrodes on first and second regions of a substrate, the first gate electrodes sequentially stacked and spaced apart from each other in a first direction, the first direction being substantially perpendicular to an upper surface of the substrate, and each of the gate electrodes extending in a second direction, the second direction being substantially parallel to the upper surface of the substrate, and
a second gate electrode over the first gate electrodes on the first region and a portion of the second region adjacent to the first region of the substrate;
memory channel structures extending through the gate electrode structure on the first region of the substrate;
support structures extending through the first gate electrodes on the second region of the substrate;
an insulating interlayer on the substrate, the insulating interlayer covering the gate electrode structure, the memory channel structures and the support structures; and
first contact plugs each extending through the insulating interlayer and at least one of the first gate electrodes to contact a first one of the first gate electrodes, each of the first contact plugs extending through but electrically insulated from a second one of the first gate electrodes that is over the first one of the first gate electrodes,
wherein each of the first contact plugs includes
an upper portion extending through the insulating interlayer, and
a lower portion under the upper portion, at least a portion of the lower portion having a width decreasing from a top toward a bottom thereof in the first direction.

17. The semiconductor device according to claim 16, wherein a width of an upper surface of the lower portion of each of the first contact plugs is greater than a width of a lower surface of the upper portion of each of the first contact plugs.

18. The semiconductor device according to claim 16, wherein
the lower portion of each of the first contact plugs includes a first lower portion and a second lower portion stacked in the first direction, and
each of the first and second lower portions of each of the first contact plugs has a width decreasing from a top toward a bottom thereof in the first direction in a stepwise manner.

19. The semiconductor device according to claim 16, further comprising:
a second contact plug extending through the insulating interlayer to contact an upper surface of the second gate electrode.

20. The semiconductor device according to claim 16, wherein
the first contact plugs are spaced apart from each other in the second direction, and
heights of lower surfaces of the first contact plugs decrease in the second direction.
